(19) United States
(12) Patent Application Publication
(10) Pub. No.: US 2006/0265865 A1
(43) Pub. Date: Nov. 30, 2006

(54) Apparatus for determining support member layout patterns

(76) Inventor: Ikuo Yoshida, Uji-shi (JP)

Correspondence Address: WENDEROTH, LIND & PONACK L.L.P., 2033 K. STREET, NW, SUITE 800, WASHINGTON, DC, 20006, US

(21) Appl. No.: 10/569,723

(22) PCT Filed: Oct. 15, 2004
(86) PCT No.: PCT/JP04/15664

§ 371 Date: Feb. 28, 2006

(30) Foreign Application Priority Data
Oct. 23, 2003 (JP) 2003-363023

(51) Int. Cl. H05K 13/04

(52) U.S. Cl. 29/729; 29/407.09; 29/407.1

(57) ABSTRACT

A support pin position determination apparatus (600) that determines the positions at which support pins are to be placed so that the leads of electronic components which have already been mounted on the undersurface of a circuit board are not damaged or the solder lands thereof do not come off includes: a database unit (607); a support pin position determination program storing unit (605); and a calculation control unit (601). The database unit (607) holds component mounting point data (607b), component shape data (607c), and available pin positions at which the support pins are allowed to be placed on a support pin plate (support pin plate data (607a)). The support pin position determination program storing unit (605) stores a support pin position determination program for determining positions at which the support pins are to be placed among the available pin positions, on the basis of the mounting point data and the shape data of the components. The calculation control unit (601) executes the support pin position determination program. The component shape data is data of the shape with a margin of a fixed width added around the outer shape of the component itself.

### TECHNICAL FIELD

The present invention relates to an apparatus for determining layout patterns of support members that support a circuit board. More particularly, it relates to an apparatus for determining positions of support pins for supporting a circuit board.

### BACKGROUND ART

In a mounter that mounts electronic components onto a circuit board such as a printed board, the circuit board is carried on a carrier rail in the mounter and positioned at a predetermined position, and then the electronic components are mounted.

In order to prevent bending of the circuit board under the weight of the circuit board itself or the weight of the electronic components mounted on the circuit board when mounting them, a supporting apparatus for supporting the circuit board by use of a plurality of support pins is provided under the carrier rail of the mounter.

As shown in FIG. 35A, a support pin plate 502 is provided in the support device. On the support pin plate 502, a plurality of pin holes 504 for setting up the support pins are provided in a grid of equal pitch.

A conventional art (See, for example, Japanese Laid-Open Patent Application Publication No. 6-169198) has suggested a method for determining the positions at which the support pins are to be set up on the plate so that they do not overlap the electronic components which are previously mounted on the undersurface of the circuit board.

FIG. 35B and FIG. 35C are the side views of the support device.

According to this conventional method, the positions of the support pins 510 are determined so that they do not hit the electronic components 508 which are mounted on the undersurface of the circuit board 20, as shown in FIG. 35B. Therefore, as shown in FIG. 35C, it is possible to move the support pin plate 502 in the direction A in FIG. 35B so as to support the circuit board 20 from the undersurface thereof, and thus prevent the bending of the circuit board 20 when mounting the electronic components on the upper surface of the circuit board 20.

In the above method, the positions of the support pins 510 are determined only in consideration that they do not overlap the electronic components 508. However, in reality, leads, solder lands, board division parts and others exist on the undersurface of the circuit board 20 where the components have already been mounted. Therefore, it is not adequate just to determine the positions of the support pins 510 so that they do not hit the electronic components 508. Even if doing so, there is still a problem that the support pins 510 hit the leads and the lands of the mounted electronic components 508 so that the leads are damaged or the solder lands come off.

In addition, in the conventional method, the positions of the support pins 510 are determined for only one layout pattern of the electronic components 508. Therefore, there is another problem that it takes a user a lot of time and trouble to determine the positions of the support pins 510 and set them up into the pin holes 504 every time the layout pattern of the electronic components 508 is changed.

In addition, since the interference between the pins and the components on only the undersurface of the circuit board is considered in the conventional method, there is further another problem that it is not possible to prevent the bending of the circuit board caused by pushing the electronic components onto the upper surface of the circuit board so as to mount them thereon.

Furthermore, in the conventional method, the pin positions for only one layout pattern of components are determined for every mounter. Therefore, there is still another problem that it takes a lot of time and trouble to determine the pin positions every time the production facility is changed or the layout pattern of the components is changed.

The present invention has been conceived in view of the above problems, and it is an object of the present invention to provide an apparatus for determining layout patterns of support pins so that the support pins do not damage the leads of the electronic components which have already been mounted on the undersurface of the circuit board or come off the solder lands thereof when the circuit board is supported by the support pins.

Another object of the present invention is to provide an apparatus for determining layout patterns of support pins so that the positions of the support pins do not need to be changed even if the layout pattern of the electronic components is changed.

Further another object of the present invention is to provide an apparatus for determining layout patterns of support pins that not only prevents the bending of the circuit board caused by the weight of the circuit board itself, but also prevents the bending of the circuit board caused by pushing of the electronic components onto the circuit board so as to mount them on the upper surface thereof.

Still another object of the present invention is to provide an apparatus for determining layout patterns of support pins that does not need to change the positions of the support pins even if the mounting facility and the layout pattern of the components are changed.

### DISCLOSURE OF INVENTION

In order to achieve the above objectives, the apparatus according to the present invention is an apparatus that determines a layout pattern of one or more support members for supporting a board, comprising: a mounting point data memory operable to hold mounting point data of a component to be mounted on a surface opposite to a mounting surface of the board; a shape data memory operable to hold shape data of the component to be mounted on the opposite surface; and a support member layout pattern determination unit operable to determine the layout pattern of the support members on the basis of the mounting point data of the component and enlarged-shape data that is data of a shape with a margin added around an outer shape of the component.

Preferably, the support members are support pins for supporting the board, and the support member layout pattern determination unit includes: a forbidden pin area determination unit operable to determine a forbidden pin area in which no support pin is allowed to be placed, on the basis of the mounting point data and the enlarged-shape data; and a support pin position determination unit operable to determine pin positions at which the support pins are to be placed, on the basis of the forbidden pin area.

For example, the forbidden pin area determination unit determines an enlarged area to be the forbidden pin area on the basis of the mounting point data and the shape data, the enlarged area being an area with a margin of a fixed width added around an outer shape of the component to be mounted on the board.

Accordingly to the above configuration, the support pin positions are determined based on the enlarged-shape data that is data of the shape with a margin of a fixed width added around the outer shape of the component. The support pin positions can also be determined so as to avoid soldering areas. Therefore, it becomes possible to avoid the support pins from hitting the lead areas and land areas on the undersurface of the board, and thus to prevent the leads of the electronic components mounted on the undersurface from being damaged and the solder lands thereof from coming off.

Preferably, the mounting point data memory holds mounting point data of each component to be mounted on each of a plurality of boards, the shape data memory holds shape data of said each component to be mounted on said each board, and the support pin position determination unit determines the pin positions on the basis of the forbidden pin area on said each board.

According to this configuration, the support pin positions are determined in consideration of the mounting point data and shape data of the components with respect to a plurality of boards. Therefore, there is no need to change the support pin positions even when the layout pattern of the electronic components is changed, so as to save users time and trouble.

More preferably, the apparatus according to the present invention further comprises an available pin position memory operable to hold available pin positions at which the support pins are allowed to be placed on a support pin plate.

Preferably, the available pin position memory holds the available pin positions on a support pin plate of each of a plurality of mounters, and the support pin position determination unit includes: a common available pin position determination unit operable to determine common available pin positions that are common to the plurality of mounters, on the basis of the available pin positions of said each mounter; and a common pin position determination unit operable to determine, among the common available pin positions, common pin positions at which the support pins are to be placed, on the basis of the forbidden pin area.

According to this configuration, the support pin positions are determined on the basis of the available pin positions that are common to the support pin plates for a plurality of mounters. Therefore, it is possible to share the support pin position information among the plurality of mounters, and thus there is no need to change the support pin layout for each mounter.

More preferably, the apparatus according to the present invention further comprises a second pin position updating unit operable to update the pin positions determined by the support pin position determination unit so that the support pins support, from under the board, surroundings of a point at which the component is to be mounted on said board.

By updating the support pin positions as described above, it becomes possible to prevent the bending of the board caused by the force exerted on the board when components are mounted.

The mounter in another aspect of the present invention is a mounter that mounts a component onto a board, comprising: a support pin plate on which one or more support pins are set up; a sensor operable to check whether or not the support pins are set up; and a warning unit operable to issue a warning when the support pin is set up at a wrong position, on the basis of pin positions determined by a support pin position determination apparatus, the pin positions being positions at which the support pins for supporting the board in the mounter are to be placed, wherein the support pin position determination apparatus includes: a mounting point data memory operable to hold mounting point data of a component to be mounted on a surface opposite to a mounting surface of the board; a shape data memory operable to hold shape data of the component to be mounted on the opposite surface; a forbidden pin area determination unit operable to determine a forbidden pin area in which no support pin is allowed to be placed, on the basis of the mounting point data and enlarged-shape data that is data of a shape with a margin added around an outer shape of the component; and a support pin position determination unit operable to determine the pin positions at which the support pins are to be placed, on the basis of the forbidden pin area.

By issuing a warning when the support pin is set up at a wrong position as described above, it becomes possible to prevent wrong placement of the support pins.

The mounter in still another aspect of the present invention is a mounter that mounts a component onto a board, comprising: a support pin plate on which one or more support pins are set up; said one or more support pins that are placed under pin holes on the support pin plate; and a support pin placement unit that places the support pins automatically by raising up the support pins through the pin holes located at pin positions determined by a support pin position determination apparatus, the pin positions being positions at which the support pins for supporting the board in the mounter are to be placed, wherein the support pin position determination apparatus includes: a mounting point data memory operable to hold mounting point data of a component to be mounted on a surface opposite to a mounting surface of the board; a shape data memory operable to hold shape data of the component to be mounted on the opposite surface; a forbidden pin area determination unit operable to determine a forbidden pin area in which no support pin is allowed to be placed, on the basis of the mounting point data and enlarged-shape data that is data of a shape with a margin added around an outer shape of the component; and a support pin position determination unit operable to determine the pin positions at which the support pins are to be placed, on the basis of the forbidden pin area.

By placing the support pins automatically as described above, it becomes possible to prevent wrong placement of the support pins.

Note that not only is it possible to embody the present invention as a variety of apparatuses for determining support pin positions including the above characteristic units, but also as a variety of methods for determining support pin positions that include, as steps, the characteristic units included in such apparatuses, and as programs that include characteristic commands. It should also be noted that such programs can be distributed on a recording medium such as a CD-ROM (Compact Disc-Read Only Memory) and via a transmission medium such as the Internet.

According to the present invention, it is possible to provide an apparatus for determining setting positions of support pins so that the leads of the electronic components which have already been mounted on the undersurface of the circuit board are not damaged, the solder lands do not come off, and needless duplication of placement of the support pins is avoided, without stopping the operation of the mounting facility for adjustment, when the circuit board is supported by the support pins. It is also possible to provide an apparatus for determining support pin positions that not only prevents the interference between the components mounted on the undersurface of the circuit board or the lands thereof and the support pins but also prevents the bending of the board when mounting the components on the upper surface of the board. Furthermore, it is possible to provide an apparatus for determining a common support pin layout so as to save time and trouble of changing the support pin positions when the layout pattern of the electronic components or the mounting facility is changed.

As further information about the technical background to this application, the disclosure of Japanese Patent Application No. 2003-363023 filed on Oct. 23, 2003 including specification, drawings and claims are incorporated herein by reference in their entirety.

### BRIEF DESCRIPTION OF DRAWINGS

These and other objects, advantages and features of the invention will become apparent from the following description thereof taken in conjunction with the accompanying drawings that illustrate a specific embodiment of the invention. In the Drawings:

FIG. 1 is an external view showing the entire construction of a component mounting system according to the present invention;

FIG. 2 is an overhead view showing the overall construction of a mounter used in the component mounting system;

FIG. 3 is a diagram showing the positional relationship between a line gang pickup head of the mounter and component cassettes;

FIG. 4A is a diagram showing one example of the specific construction of the four component supplying units within the two stages provided in the mounter;

FIG. 4B is a table showing the number of component cassettes of various types and their positions on the Z-axis in the construction of FIG. 4A;

FIG. 5A is a diagram showing examples of the positions in the Z-axis of component supplying units where components can be picked up by the line gang pickup head with ten nozzles;

FIG. 5B is a table for explaining the positions in the Z-axis shown in FIG. 5A;

FIGS. 6A to 6D are diagrams showing various chip-shaped electronic components to be mounted;

FIG. 7 is a diagram showing one example of a carrier tape that holds components and a supply reel for this carrier tape;

FIG. 8 is a diagram showing an example of a component cassette in which taped electronic components have been loaded;

FIG. 9 is a block diagram showing the hardware construction of an optimization apparatus;

FIG. 10 is a diagram showing an example of the mounting point data as shown in FIG. 9;

FIG. 11 is a diagram showing an example of a component library as shown in FIG. 9;

FIG. 12 is a diagram showing an example of mounter information as shown in FIG. 9;

FIG. 13 is an external view of a support pin plate, a support pins and others;

FIG. 14 is a block diagram showing a hardware construction of a support pin position determination apparatus;

FIG. 15 is a diagram showing one example of support pin plate data;

FIG. 16 is a diagram for explaining a size of an electronic component;

FIG. 17 is a diagram for explaining a shape of an electronic component land;

FIG. 18 is a flowchart showing a support pin position determination process;

FIG. 19 is a diagram showing one example of an effective support pin plate data area;

FIG. 20A is a diagram for explaining mounting board information;

FIG. 20B is a diagram for explaining flipped mounting board information;

FIG. 21 is a diagram showing another example of the effective support pin plate data area;

FIG. 22(a) is a diagram showing one example of superimposed data which is obtained by superimposing the effective support pin plate data area and the flipped mounting board information;

FIG. 22(b) is a diagram showing one example of support pin position data;

FIG. 23 is a diagram for explaining a process of creating the support pin position data;

FIG. 24 is a diagram for schematically explaining the process of creating the support pin position data based on a plurality of circuit boards;

FIG. 25 is a diagram showing one example of support pin position information displayed on a display unit;

FIG. 26 is a diagram showing another example of the support pin position information displayed on the display unit;

FIG. 27 is a flowchart of an automatic optimum support pin position calculation process;

FIG. 28 is a diagram showing one example of an ideal layout mask of pin positions in a grid of the pitch “1”;

FIG. 29 is a diagram showing one example of an ideal layout mask of pin positions in a grid of the pitch “2”;

FIG. 30 is a diagram showing one example of the support pin position data;

FIG. 31 is a diagram showing effective pin positions obtained as a result of superimposing the support pin position data as shown in FIG. 30 on the layout mask as shown in FIG. 28;

FIG. 32 is a diagram showing effective pin positions obtained as a result of superimposing the support pint position data as shown in FIG. 30 on the layout mask on which the pin positions are shifted by one pitch in the X direction from those on the layout mask as shown in FIG. 28;

FIG. 33 is a diagram for explaining the weighting of the support pins;

FIG. 34 is a diagram showing one example of a jig made of polyurethane foam; and

FIG. 35A to FIG. 35C are diagrams for explaining a conventional apparatus for supporting a circuit board.

### BEST MODE FOR CARRYING OUT THE INVENTION

Referring to the drawings, the following describes the component mounting system according to the embodiment of the present invention.

<Mounting System>

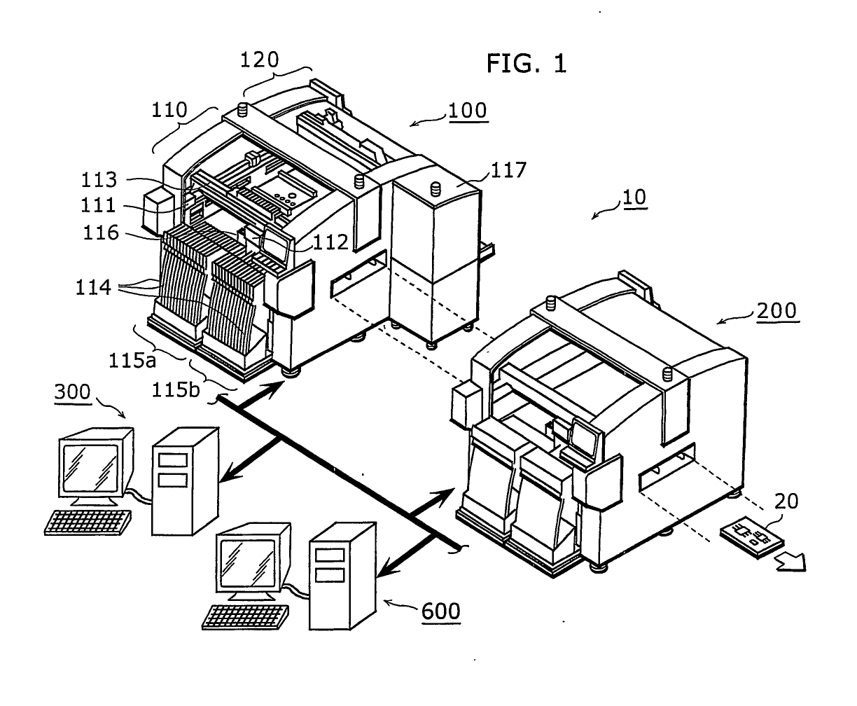

FIG. 1 shows the entire construction of a mounting system 10 according to the present invention. As shown in the drawing, the mounting system 10 is composed of a plurality (here, two) of mounters 100 and 200, an optimization apparatus 300 and a support pin position determination apparatus 600. The mounters 100 and 200 form a production line where electronic components are mounted onto a circuit board 20 that is transported downstream. The optimization apparatus 300 optimizes the mounting order of the required electronic components at the start of production, for example, based on information in a variety of databases, and sets and controls the mounters 100 and 200 having provided them with the numeric control (NC) data produced by the optimization. The support pin position determination apparatus 600 determines the positions of the support pins that support the circuit board 20 when mounters 100 and 200 mount the components.

The mounter 100 is equipped with two stages (a front stage 110 and a rear stage 120) that operate simultaneously and independently of one another, or in concert, or even alternately. Each of these stages 110 and 120 is a perpendicular robotic mounting stage and includes two component supplying units 115a and 115b, a line gang pickup head 112, an XY robot 113, a component recognizing camera 116, and a tray supplying unit 117. The component supplying units 115a and 115b are each made up of an array of up to 48 component cassettes 114 that store component tapes. The line gang pickup head 112 has 10 pickup nozzles (hereafter simply “nozzles”) that can pick up a maximum of 10 components from the component cassettes 114 and mount them onto the circuit board 20. The XY robot 113 moves the line gang pickup head 112. The component recognizing camera 116 investigates the picked-up state of the components that have been picked up by the line gang pickup head 112 in two or three dimensions. The tray supplying unit 117 supplies tray components. The front and rear stages mount components onto a board independently of or in parallel with the other stage.

In this specification, the expression “component tape” refers to a tape (a carrier tape) in which a number of the same type of components have been arranged, with such tape being supplied from a reel (a supply reel) or the like around which the tape has been wound. Component tapes are usually used to supply relatively small components called “chip components” to a mounter. However, during the optimization process, a “component tape” refers to data that specifies a group of components of the same type that are assumed to have been arranged on a virtual tape. In the process called “component division”, a group of components of the same type (that would potentially be arranged on a single component tape) are divided into a plurality of component tapes. Note that the expression “component type” refers to a type of electronic components such as resistor and capacitor.

It should also be noted that components supplied by a component tape are sometimes called “taped components”.

In more detail, the mounter 100 is a mounting device that includes the functions of both a mounting device commonly called a high-speed mounter and a mounting device called a multi-function mounter. A high-speed mounter is a device that is capable of mounting electronic components that are 10 mm² or smaller in around 0.1 seconds per component, while a multi-function mounter is a device that can mount large electronic components that are 10 mm² or larger, irregularly shaped components like switches and connectors, and IC components like QFP (Quad Flat Package) or BGA (Ball Grid Array) components.

In short, the mounter 100 is designed so as to be able to mount almost all types of electronic components from 0.6 mm by 0.3 mm chip resistors to 200 mm connectors, with a production line being formed by arranging the required number of mounters 100 in a line.

<Construction of the Mounter>

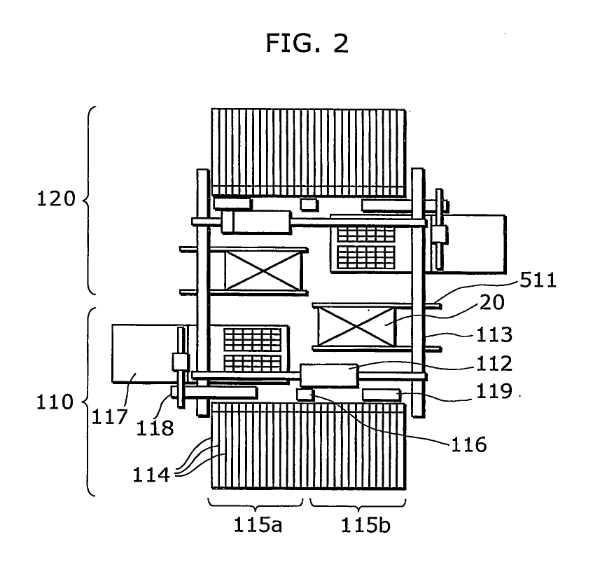

FIG. 2 is an overhead view showing the overall construction of the mounter 100 intended for the optimization of the mounting order.

A shuttle conveyor 118 is a moving table on which a component taken from the tray supplying unit 117 is placed and which is moved to a predetermined position where the line gang pickup head 112 can pick up components from the shuttle conveyor 118. A nozzle station 119 is a table on which interchangeable nozzles corresponding to various sizes of components are positioned.

The component supplying units 115a and 115b included in each stage 110 and 120 are provided on the left and right sides of the component recognizing camera 116. The line gang pickup head 112 picks up components from the component supplying unit 115a or 115b, passes by the component recognizing camera 116, and then repeats an operation whereby the line gang pickup head 112 moves to a mounting point on the circuit board 20 and mounts one of the picked-up components. Note that the expression “mounting point” refers to a coordinate point on a board on which a component should be mounted, and that it is possible that components of the same component type are mounted on different points. The total number of components (mounting points) to be arranged on a component tape for a certain component type equals the number of components belonging to such component type (the total number of components that should be mounted).

In this specification, one iteration of the repeated series of processes where the line gang pickup head 112 picks up, transports, and mounts components and the group of components handled in such iteration are both referred to as a “task”. As one example, when the line gang pickup head 112 has ten nozzles, the maximum number of components that can be mounted by a single task is ten. It should also be noted that a “pickup operation” refers to all of the operations performed from when the head starts to pick up components to when the line gang pickup head 112 transports the components. In this specification, a pickup operation refers not only to when ten components are picked up by the line gang pickup head 112 with a single nozzle stroke (a raising and lowering of the line gang pickup head 112), but also to when ten components are picked using several nozzle strokes.

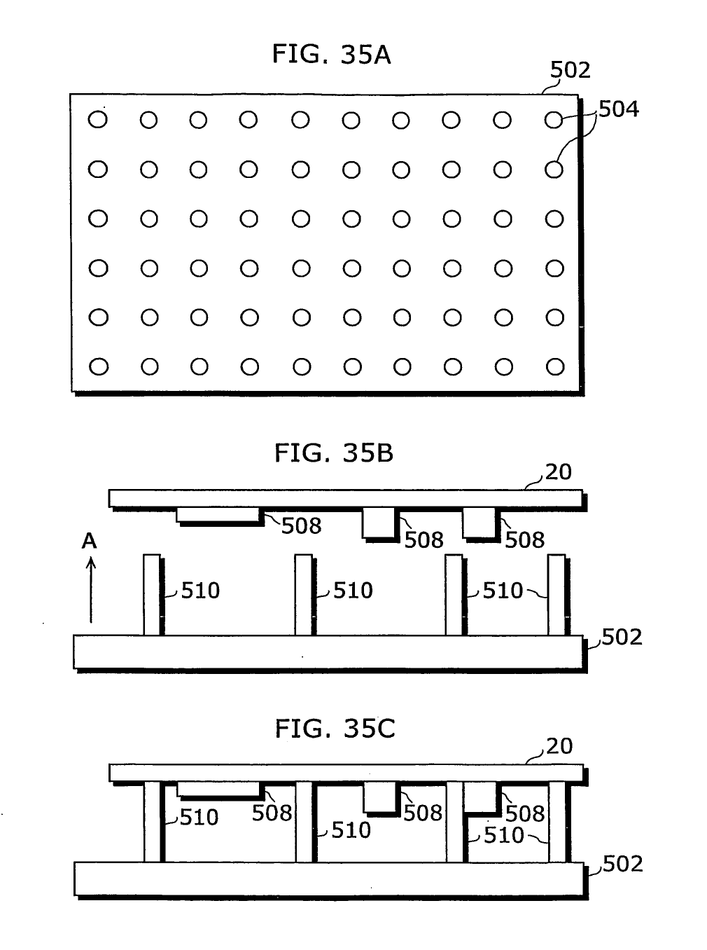

Note that the circuit board 20 on which the components are to be mounted is carried on the carrier rail 511, fastened in a predetermined position, and then the components are mounted on the circuit board 20. A support device for supporting the circuit board 20 is provided under the carrier rail 511. Since this support device is same as the support device as described by referring to FIG. 35A to FIG. 35C, the detailed explanation thereof is not repeated here.

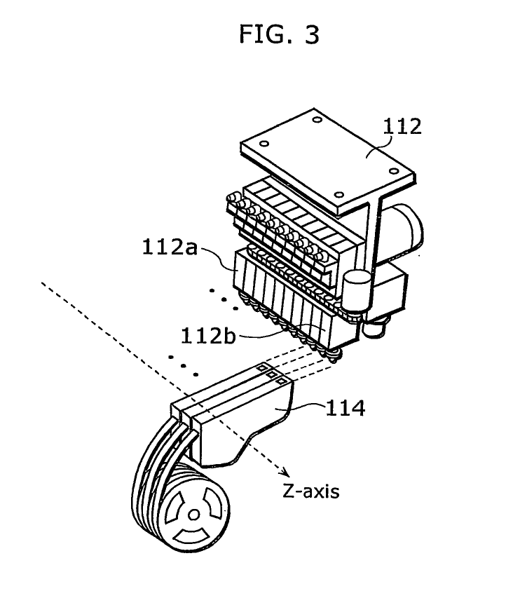

FIG. 3 is a depiction of the positional relationship between the line gang pickup head 112 and the component cassettes 114. The line gang pickup head 112 uses a method referred to as “gang pickup” and can be equipped with a maximum of ten pickup nozzles 112a-112b. When thus equipped, a maximum of ten components can be simultaneously picked up from the component cassettes 114 in a single nozzle stroke (one raising and lowering of the line gang pickup head 112).

Note that only one component tape is loaded into a “single cassette” component cassette 114, while two component tapes are loaded into a “double cassette” component cassette 114. The position of each component cassette 114 (or component tape) in a component supplying unit 115a or 115b is indicated using a value in the Z-axis or a position on the Z-axis, with consecutive values being assigned to positions starting with the leftmost position in the component supplying unit 115a as position “1”. Therefore, in order to determine the mounting order for taped components, it is necessary to determine the ordering (i.e., positioning on the Z-axis) of components (or component tapes, or component cassettes 114 in which the component tapes have been loaded). Here, “Z-axis” refers to a coordinate axis (or coordinate values thereon) to specify arrangement positions of component cassettes that are placed for each mounter (stage when it is equipped).

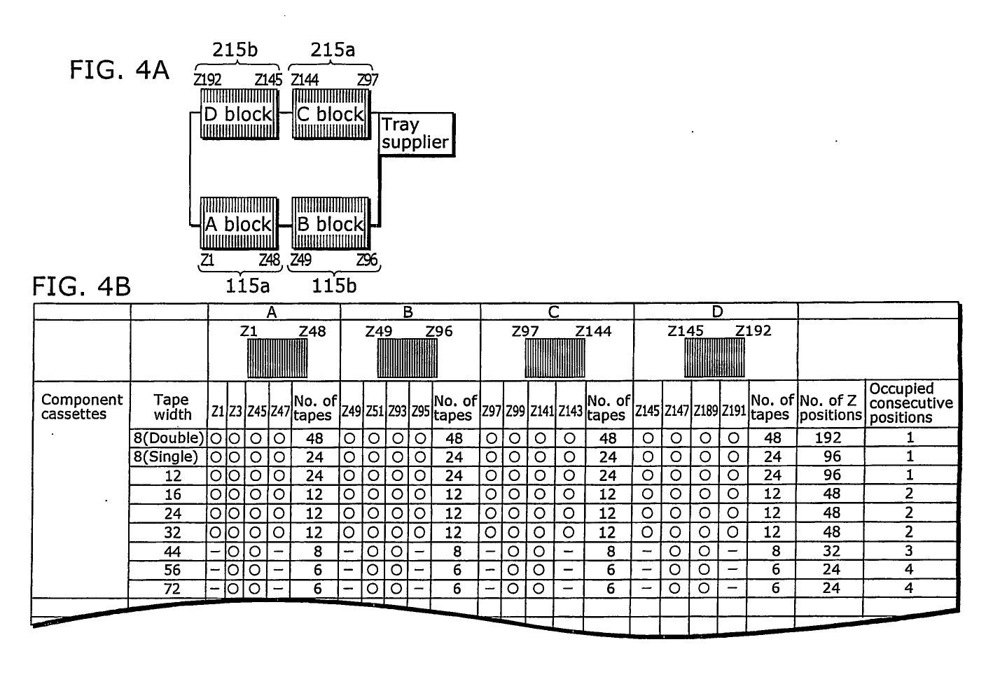

As shown in FIG. 4A, the component supplying units 115a, 115b, 215a, and 215b are each capable of storing a maximum of 48 component tapes, with the positions in these component supplying units being respectively numbered Z1 to Z48, Z49 to Z96, Z97 to Z144, and Z145 to Z192. As shown in FIG. 4B, by using double cassette feeders that can store two 8 mm-wide component tapes, each component supplying unit (A block to D block) can supply a maximum of 48 types of components. The wider the component tapes (component cassettes) used in a component supplying unit, the lower the number of feeders that can be loaded into a single block.

Note that in this specification, the leftmost component supplying units 115a and 215a (Block A and Block C) in each stage are referred to as the “left blocks”, while the rightmost component supplying units 115b and 215b (Block B and Block D) in each stage are referred to as the “right blocks”.

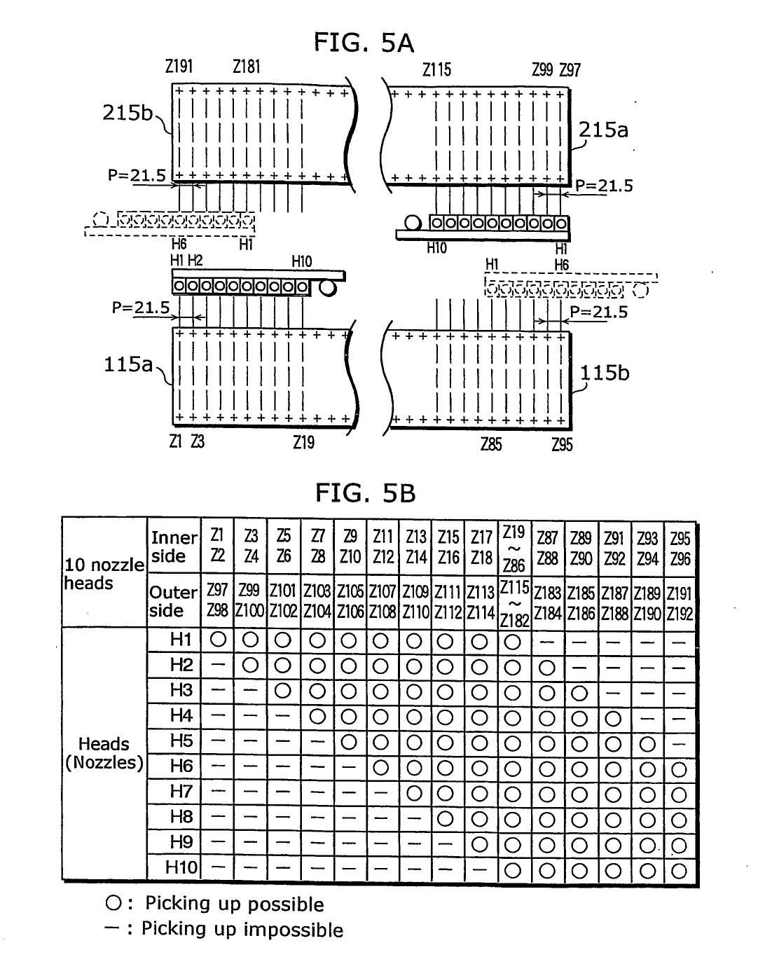

FIGS. 5A and 5B are a drawing and table showing examples of the positions in the Z-axis of component supplying units where components can be picked up by a line gang pickup head with ten nozzles. Note that the values given as H1 to H10 in these drawings represent the positions of the ten nozzle heads.

The intervals between the nozzle heads are equivalent to the width (21.5 mm) of one double-cassette feeder, so that the Z numbers of the components that can be picked up in a single nozzle stroke are two numbers apart (i.e., either all odd or all even). Due to the restrictions on the movement of a line gang pickup head with ten nozzles in the Z-axis, there are cases where certain nozzles are incapable of picking up components positioned near the ends of the component supplying units. Such cases are indicated by the “-” marks in FIG. 5B.

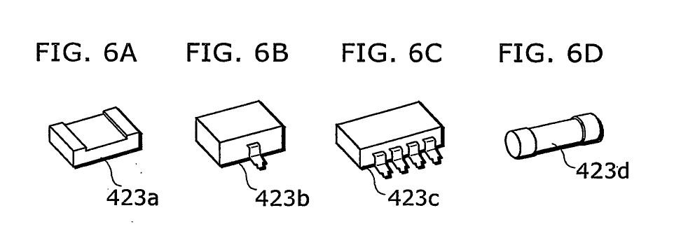

The following describes the construction of a component cassette 114 in detail, with reference to FIGS. 6A to 8.

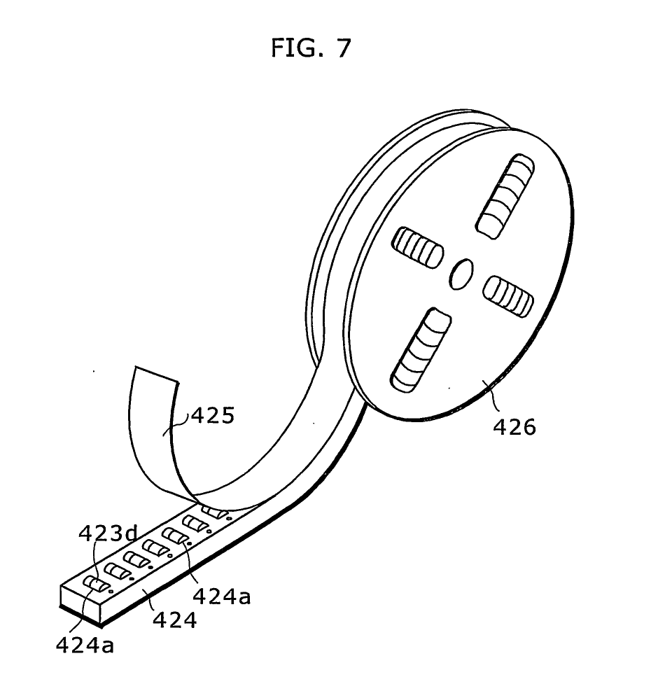

FIGS. 6A to 6D show various chip-shaped electronic components 423a to 423d. As shown in FIG. 7, components 423d are placed into concave-shaped storage spaces 424a that are successively formed in a carrier tape 424 and are encapsulated by applying a cover tape 425 over the carrier tape 424. A predetermined length of this carrier tape 424 is wound around the supply reel 426, and the result is supplied to users as a component tape. Note, however, that the shape of spaces in which electronic components are stored is not limited to a concave shape. The carrier tape 424 shown in FIG. 7 may be substituted by an adhesive tape on which components are fixed adhesively as well as a paper tape.

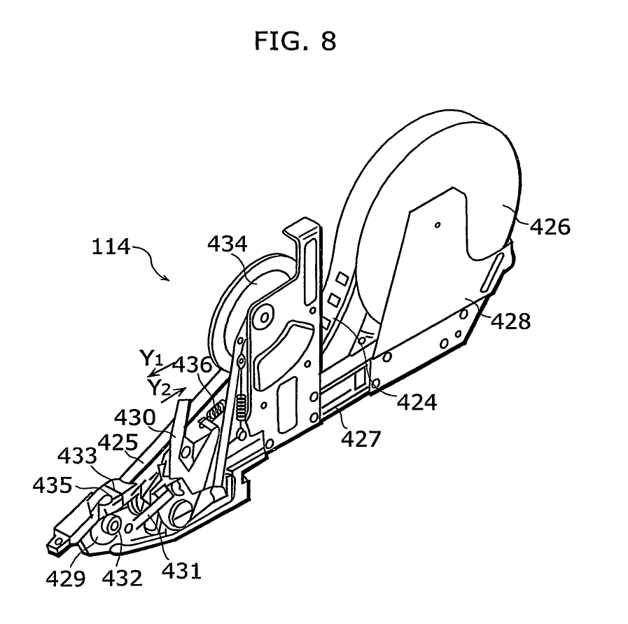

Taped components such as electronic component 423d are used having first been loaded into a component cassette 114, such as that shown in FIG. 8. In FIG. 8, the supply reel 426 is attached to reel side plates 428 so as to be freely rotatable, with the reel side plates 428 engaging a main frame 427. Carrier tape 424 that has been pulled off the supply reel 426 is guided by a feed roller 429. An automatic electronic component mounting apparatus (not illustrated) in which this electronic component supplying apparatus has been fitted operates as follows. Movement of a feed lever (not illustrated) also fitted in the apparatus causes a feed lever 430 of the electronic component supplying apparatus to move in the direction shown as Y₁ in FIG. 8. This movement is transmitted via a link 431 attached to the feed lever 430 and results in a ratchet 432 rotating by a predetermined angle. The feed roller 429 is disposed so as to move in conjunction with the ratchet 432, and so moves by a fixed pitch, such as a feed pitch of 2 mm or 4 mm. Note that the carrier tape 424 may be fed from the reel by a motor drive or a cylinder drive.

The cover tape 425 is peeled off the carrier tape 424 by a cover tape separating unit 433 that is positioned before the feed roller 429 (towards the supply reel 426). The separated cover tape 425 is wound around a cover tape collecting reel 434 and the carrier tape 424 from which the cover tape 425 has been removed is transported to the electronic component removing unit 435. At the same time as the carrier tape 424 is fed by the feed roller 429, the electronic component removing unit 435 opens in conjunction with the movement of the ratchet 432, and a vacuum suction head (not illustrated) picks up a chip-shaped electronic component 423d using suction, thereby removing it from a storage space 424a. After this, the pressing force applied by the feed lever of the apparatus is removed and the force applied by a tension spring 436 causes the feed lever 430 to move in the direction shown as Y₂ in FIG. 8. As a result, the feed lever 430 returns to its original position.

The characteristic operations of the mounter 100 are as follows.

(1) Nozzle Interchanging

When a nozzle that is required for the next mounting operation is not present on the line gang pickup head 112, the line gang pickup head 112 is moved to the nozzle station 119 where nozzle interchanging is performed. The types of nozzles available depend on the sizes of the components to be picked up by the line gang pickup head 112. As one example, “type S”, “type M”, and “type L” nozzles may be provided.

(2) Component Pickup

The line gang pickup head 112 moves to the component supplying units 115a and 115b and picks up electronic components using suction. When ten components cannot be simultaneously picked up, the line gang pickup head 112 may be repositioned and may make several nozzle strokes to pick up a maximum of ten electronic components.

(3) Recognition Scan

The line gang pickup head 112 moves past the component recognizing camera 116 at a predetermined speed. The component recognizing camera 116 forms images of all of the electronic components that have been picked up by the line gang pickup head 112 and detects whether the components have been picked up at the correct positions.

(4) Component Mounting

Electronic components are successively mounted on the circuit board 20.

The above operations (1) to (4) are repeated, thereby mounting all of the required electronic components onto the circuit board 20. The operations (2) to (4) form the main operation of the mounter 100 when mounting components and correspond to a “task”. This means that a maximum of ten electronic components can be mounted on a board in a single task.

<Restrictions for the Mounter>

The object when optimizing the order of mounting for components is to maximize the number of boards that can be processed by the mounter 100 per unit time. As can be understood from the functional and operational characteristics of the mounter 100 that are mentioned above, a favorable optimization method (optimization algorithm) is one that selects ten electronic components that can be efficiently mounted onto a board, simultaneously picks up all ten from a component supplying unit, and then successively mounts the electronic components using the shortest possible route. The order of component mounting determined by such an optimization algorithm will ideally result in ten times the productivity of the case where a mounter is only equipped with one nozzle.

However, due to factors such as device construction, cost, and operability, every mounter is subject to certain restrictions regarding the order in which components can be mounted. More realistically, the optimization of the order of component mounting is therefore the maximization of the number of boards that can be processed by the mounter per unit time, subject to various restrictions.

The following describes the main restrictions to which the mounter 100 is subject.

<Line Gang Pickup Head>

The line gang pickup head 112 has ten mounting heads that can independently pick up and mount electronic components arranged in a line. A maximum of ten pickup nozzles can be attached, so that a maximum of ten components can be picked up in a single nozzle stroke by the line gang pickup head 112.

Each of the heads (a part capable of picking up one component) that compose the line gang pickup head 112 is referred to in this specification as a “mounting head” or simply as a “head”.

The ten mounting heads that form the line gang pickup head 112 are arranged in a straight line, which places a restriction on the movable range of the line gang pickup head 112, both when picking up components and when mounting components. In more detail, as shown in FIG. 5B, there are restrictions as to which mounting heads are able to access components that are located at either end of a component supplying unit (which is to say, near the left end of the left component supplying unit 115a and near the right end of the right component supplying unit 115b).

When mounting electronic components onto a board, there are also restrictions on the movable range of the line gang pickup head 112.

<Component Recognizing Camera>

As the component recognizing camera 116, the mounter 100 is equipped with a 2D camera that forms two-dimensional images and a 3D camera that can also detect height. As the 2D camera, a 2DS camera and 2DL camera are provided for use, depending on the size of the area to be photographed. The 2DS camera is capable of photographing a small area at high speed, while the 2DL camera is characterized by having maximum field of 60 mm by 220 mm. The 3D camera is used to detect in three dimensions whether any of the leads of an IC component are bent.

The recognition scanning speed used when photographing electronic components differs depending on the camera being used. When components that are photographed by the 2DS camera and components that are photographed by the 3D camera are present in the same task, recognition scanning needs to be performed at the scanning speed of each camera, making two scanning operations necessary.

<Component Supplying Units>

Electronic components may be packaged in the form of a component tape, where components are held by a tape, or in the form of a tray in the form of a plate whose area is partitioned in keeping with the dimensions of components.

The supply of taped components is performed by the component supplying units 115a and 115b, while the supply of tray components is performed by the tray supplying unit 117.

The taping of electronic components is standardized, and tapes with widths of 8 mm to 72 mm are available for different-sized components. By setting components that are held by a tape (or in other words, a “component tape”) in a component cassette (a “tape feeder unit”) with a suitable width for the tape width, electronic components can be reliably and consecutively obtained from the tape.

The component supplying units in which component cassettes are set are designed so that component tapes with a width of up to 12 mm can be loaded with no gaps at a pitch of 21.5 mm. When the width of the tape is 16 mm or above, tapes need to be set leaving an appropriate gap that depends on the width of the tape. In order to pick up a plurality of electronic components simultaneously (i.e., in a single nozzle stroke for the line gang pickup head 112), the mounting heads and component cassettes should be aligned with the same pitch. When each component is supplied using a tape that is 12 mm wide or narrower, ten components can be simultaneously picked up by the line gang pickup head 112.

Note that the two component supplying units (the left block 115a and right block 115b) that compose each component supplying unit are each capable of holding a maximum of 48 tapes that are 12 mm wide or narrower.

<Component Cassettes>

Component cassettes can be single-cassette feeders that only hold one component tape or double-cassette feeders that hold a maximum of two cassettes. The two component tapes that are placed in the same double-cassette feeder need to have the same feed pitch (2 mm or 4 mm).

<Other Restrictions>

In addition to the above restrictions that arise due to the construction of the mounter 100, the mounter 100 is also subject to the following operation restrictions that arise due to the production facility in which the mounter 100 is being used.

(1) Fixed Arrangements

As one example, in order to reduce the amount of labor required to replace component tapes, there are cases where a particular component tape (or the component cassette that holds this component tape) is set at a fixed position (a position on the Z-axis) within a component supplying unit.

(2) Restrictions on Resources

There are cases where the number of component tapes that are provided for the same type of components, the number of feeders used to hold component tapes, the number of double-cassette feeders, and the number of nozzles (of each type) are subject to certain restrictions.

<Optimization apparatus>

The optimization apparatus 300 is an apparatus that determines the order of component mounting that enables the finished board to be produced in the shortest possible time to raise the number of boards that can be produced per unit time, when informed of the article to be produced (the board and the components to be mounted upon it) and the production machinery (the mounters and stages with their limited resources).

In more detail, in order to minimize the amount of time spent mounting components on each board, a computer decides at what positions (Z-axis) in what mounter (stage) the component cassettes loaded with component tapes should be set, in what order the line gang pickup head of each mounter (stage) should pick up the highest possible numbers of components as possible from the component cassettes, and in what order and at which positions (mounting points) the picked-up components should be mounted on a board. The computer makes this decision by finding an optimal solution.

When doing so, the optimization needs to satisfy the aforementioned restrictions present with the mounters (stages) being used.

<Hardware Construction of the Optimization Apparatus>

The optimization apparatus 300 is realized by having a standard computer system such as a personal computer execute an optimization program embodying the present invention. When not connected to an actual mounter 100, the optimization apparatus 300 can also function as a stand-alone simulator (an optimization tool for the order of component mounting).

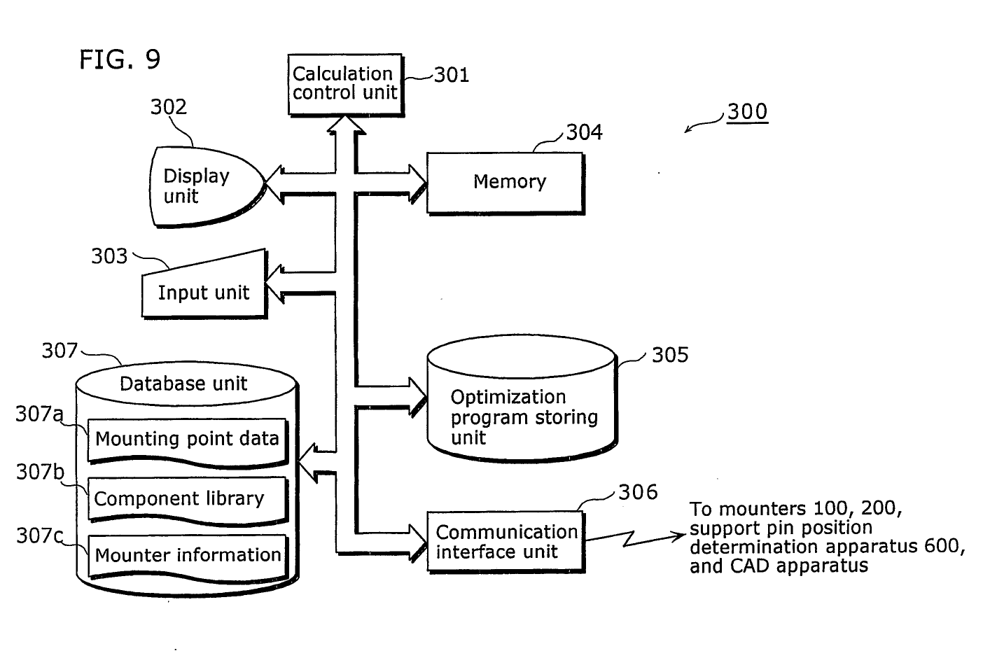

FIG. 9 is a block diagram showing the hardware construction of the optimization apparatus 300 that was shown in FIG. 1. In order to minimize the line tact time (the highest tact time out of the individual tact times of the stages forming the production line) for the mounting of components on a board under various restrictions that arise due to the performance specifications of the production facilities that compose the production line, the optimization apparatus 300 determines which components should be mounted by each stage and the mounting order of components for each stage, based on information for all of the components that is provided by a component mounting CAD (Computer-Aided Design) apparatus or the like. By doing so, the optimization apparatus 300 produces optimal NC data. As shown in FIG. 9, the optimization apparatus 300 includes a calculation control unit 301, a display unit 302, an input unit 303, a memory 304, an optimization program storing unit 305, a communication interface unit 306, and a database unit 307.

It should be noted that in this specification, the expression “tact time” refers to the total time required to mount components The calculation control unit 301 is a CPU (Central Processing Unit), a numeric processor, or the like. In accordance with instructions from the user, the calculation control unit 301 loads the required programs from the optimization program storing unit 305 into the memory 304 and executes them. In accordance with the execution result, the calculation control unit 301 controls the constituent units numbered 302 to 307.

The display unit 302 is a CRT (Cathode Ray Tube), an LCD (Liquid Crystal Display), or the like, while the input unit 303 is an input device such as a keyboard or a mouse. These components are controlled by the calculation control unit 301 and are used to allow user interaction with the optimization apparatus 300.

The communication interface unit 306 is a LAN (Local Area Network) adapter or the like, and is used to allow the optimization apparatus 300 to communicate with the mounters 100 and 200, the support pin position determination apparatus 600, and the CAD apparatus (not illustrated) that designs the layouts of electronic components, wiring patterns or the like.

The memory 304 is a RAM (Random Access Memory) or the like that provides a work area for the calculation control unit 301. The optimization program storing unit 305 is a hard disk or the like storing a variety of optimization programs that realize the functions of the optimization apparatus 300.

The database unit 307 is a hard disk or the like storing input data (mounting point data 307a, a component library 307b, and mounter information 307c) that is used in the optimization process performed by the optimization apparatus 300 and mounting point data and other data generated by the optimization process.

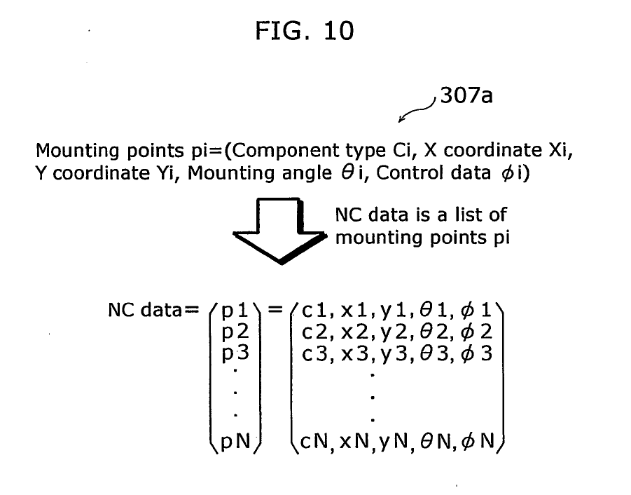

FIGS. 10 to 12 show examples of the mounting point data 307a, the component library 307b, and the mounter information 307c, respectively.

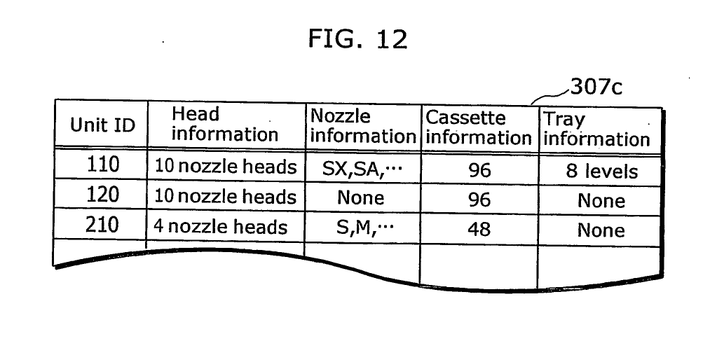

The mounting point data 307a is a collection of information showing the mounting points of all of the components to be mounted. As shown in FIG. 10, one mounting point pᵢ is made up of a component type cᵢ, an X coordinate xᵢ, a Y coordinate yᵢ, a mounting angle θᵢ, and control data φᵢ. In the present case, the expression “component type” refers the name of a component in the component library 307b shown in FIG. 12, the “X coordinate” and “Y coordinate” are the coordinates of the mounting point (coordinates that indicate a specific position on a board), the “mounting angle” is the rotation angle of the head during mounting the components, and the “control data” is restriction information (such as the type of pickup nozzle that can be used and the maximum speed at which the line gang pickup head 112 should move) relating to the mounting of the component. It should be noted that the “NC data” that is to be finally produced is an ordered list of mounting points that results in the shortest line tact time. It should also be noted that the X axis direction is the traveling direction of the circuit board 20, while the Y axis direction is the direction orthogonal to the X axis direction.

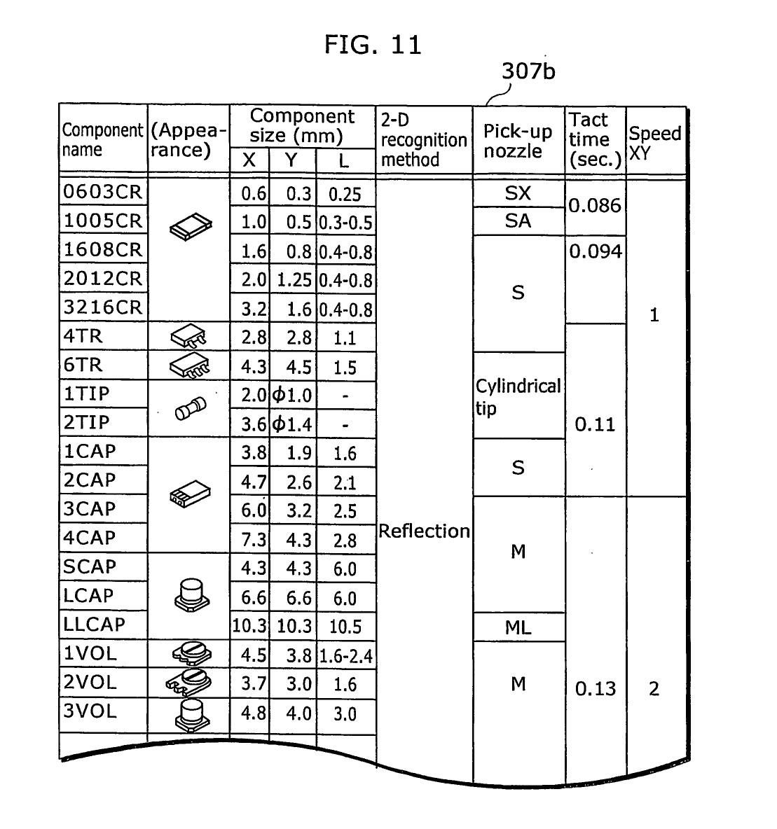

The component library 307b is a library in which specific information for the various component types that can be handled by the mounters 100 and 200 is gathered together. As shown in FIG. 11, each entry in the component library 307b includes the component size, tact time (tact time for each component type subject to certain conditions), and other restriction information (such as the type of pickup nozzle that can be used, the recognition method to be used by the component recognizing camera 116, and the maximum speed at which the line gang pickup head 112 should move). It should be noted that in FIG. 11, the external appearance of components of various types have also been shown for reference purposes.

The mounter information 307c is information showing the constructions of each of the stages forming the production line and the restrictions to which these stages are subject. As shown in FIG. 12, the mounter information 307c is made up of information such as unit IDs indicating stage numbers, head information relating to the type of line gang pickup head, nozzle information relating to the types of nozzles that can be attached to the line gang pickup head, feeder information relating to the maximum number of component cassettes 114, and tray information relating to the number of levels on which trays are stored in the tray supplying unit 117.

The information described above is categorized as follows. The categories used are equipment option data (for each stage), resource data (the number of cassettes that can be fitted in each stage and the number of nozzles in each stage), nozzle station arrangement data (for each station equipped with a nozzle station), initial nozzle pattern data (for each stage), and Z-axis arrangement data (for each stage).

<Support Pin Position Determination Apparatus>

The support pin position determination apparatus 600 is an apparatus for determining the positions of the pin holes 504 on the support pin plate 502 for setting up the support pins 510 thereon, based on the support pin plate data regarding the shape of the support pin plate 502, component mounting point data, component shape data, component land information, and contour information of the circuit board 20.

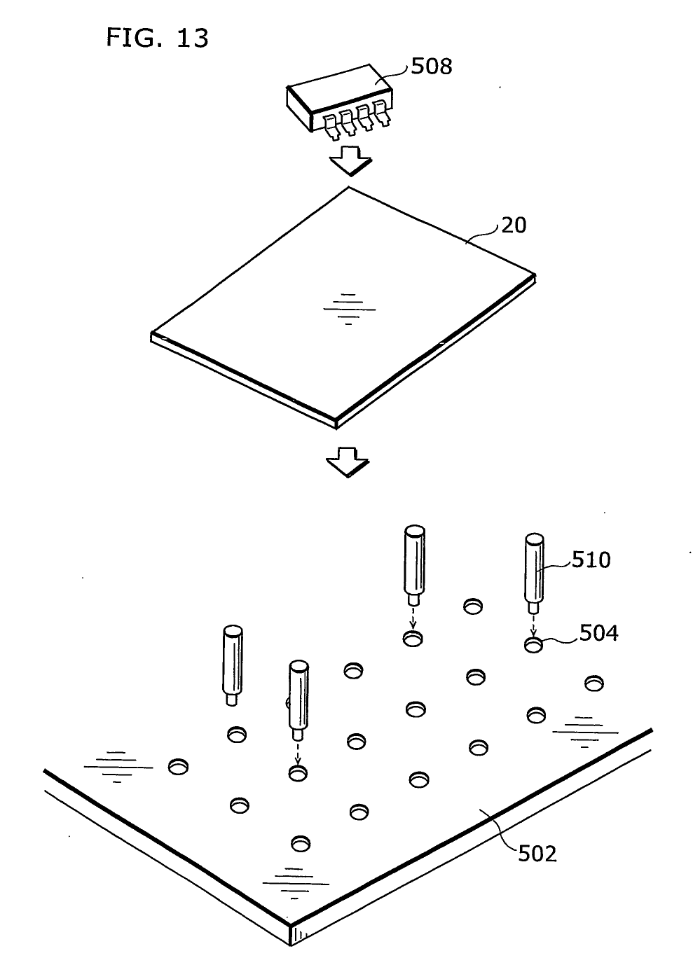

FIG. 13 is an external view of the support pin plate 502, the support pins 510 and others. Prior to the mounting of the electronic component 508, a user sets up the support pins 510 in the pin holes 504 on the support pin plate 502. The circuit board 20 is placed on the support pins 510, and the electronic component 508 is mounted on the circuit board 20 by the line gang pickup head 112.

<Hardware Construction of the Support Pin Position Determination Apparatus>

The support pin position determination apparatus 600 is realized by having a standard computer system such as a computer execute a support pin position determination program embodying 25 the present invention. When not connected to an actual mounter 100, the support pin position determination apparatus 600 can also function as a stand-alone simulator (a tool for the support pin position determination).

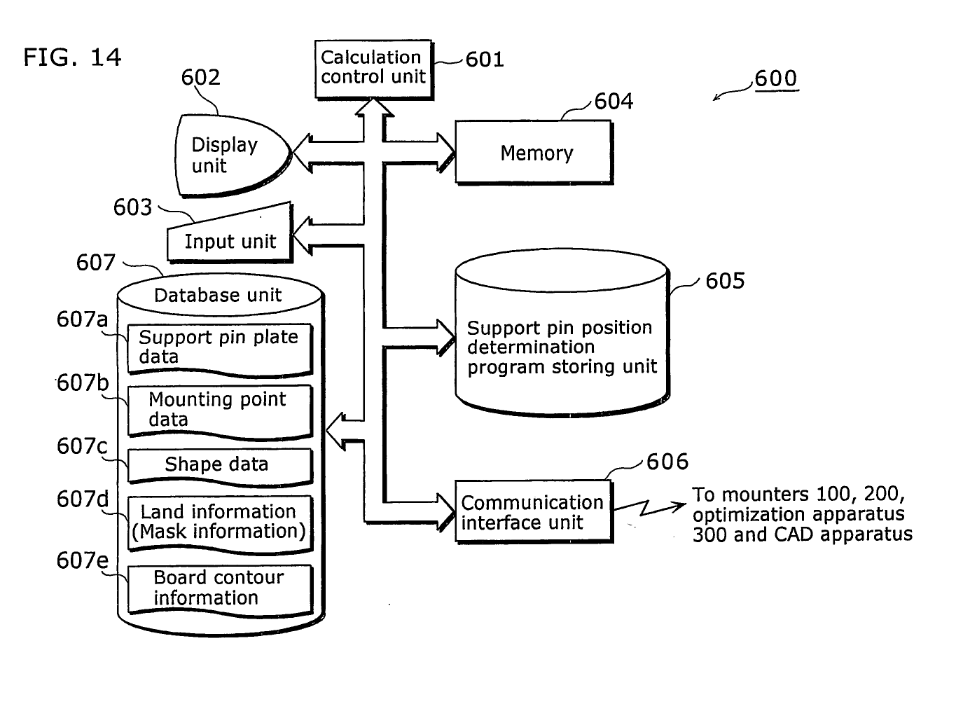

FIG. 14 is a block diagram showing the hardware construction of the support pin position determination apparatus 600 that was shown in FIG. 1. The support pin position determination apparatus 600 determines, based on the mounting points of the components to be mounted on the circuit board 20, the positions of the pin holes 504 for setting up the support pins 510 on the support pin plate 502 of the support device of each stage, and generates the optimum position information of the support pins 510. As shown in FIG. 14, the support pin position determination apparatus 600 includes a calculation control unit 601, a display unit 602, an input unit 603, a memory 604, a support pin position determination program storing unit 605, a communication interface unit 606, and a database unit 607.

The calculation control unit 601 is a CPU, a numeric processor, or the like. In accordance with instructions from the user, the calculation control unit 601 loads the required programs from the support pin position determination program storing unit 605 into the memory 604 and executes them. In accordance with the execution result, the calculation control unit 601 controls the constituent units numbered 602 to 607.

The display unit 602 is a CRT, an LCD or the like, while the input unit 603 is an input device such as a keyboard or a mouse. These components are controlled by the calculation control unit 601 and are used to allow user interaction with the support pin position determination apparatus 600.

The communication interface unit 606 is a LAN adapter or the like, and is used to allow the support pin position determination apparatus 600 to communicate with the mounters 100 and 200, the optimization apparatus 300, and the above-mentioned CAD apparatus (not illustrated).

The memory 604 is a RAM or the like that provides a work area for the calculation control unit 601. The support pin position determination program storing unit 605 is a hard disk or the like storing a variety of programs that realize the functions of the support pin position determination apparatus 600.

The database unit 607 is a hard disk or the like storing the input data (support pin plate data 607a, mounting point data 607b, shape data 607c, land information 607d, and board contour information 607e) that are used in the support pin position determination process performed by the support pin position determination apparatus 600, and the support pin position information and other data that are generated in the support pin position determination process.

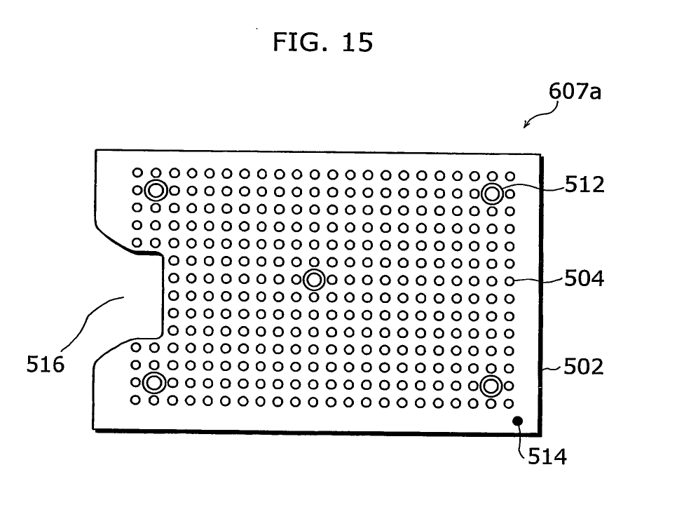

As shown in FIG. 15, the support pin plate data 607a indicates the shape of the support pin plate 502 that composes the support device for the circuit board 20 and the positions of available pin holes 504 at which the support pins 510 can be placed. A part of the pin holes 504 is missing because of a cut-away part 516 of the support pin plate data 607a, bolt positions 512 and the like. The support pin plate data 607a also indicates the position of the reference hole for aligning with the circuit board 20.

The mounting point data 607b is a collection of information showing the mounting points of all of the components to be mounted. This mounting point data 607a is same as that shown in FIG. 10. It should be noted that the calculation control unit 601 does not always need to store the mounting point data 607b into the database unit 607. Instead, it may use the mounting point data 307a stored in the optimization apparatus 300 via the communication interface unit 606.

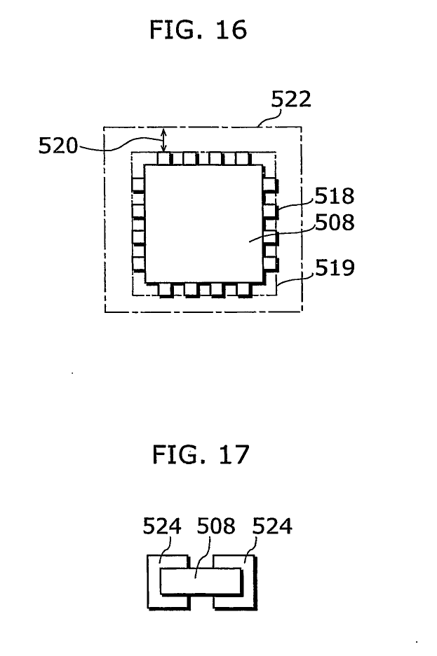

The shape data 607c is the data of a component shape, including at least the component name and the component size among the information included in the component library 307b as shown in FIG. 11. It should be noted that the component size here means the size of a circumscribed rectangle 522 with a margin of fixed width 520 added around a circumscribed rectangle 519 including the electronic component 508 or another electronic component itself and the leads 518 thereof, as shown in FIG. 16. In more detail, the fixed width margin 520 may be determined based on the land position and the land shape because it includes an area where solder is applied for soldering the electronic component 508 or the like. It should be noted that the fixed width margin 520 may be determined for every type of electronic components or may be determined across the board for all the electronic components. It is possible to determine, with higher precision, the areas where the support pins should not be set up, if the margin is determined for each type of electronic components.

As shown in FIG. 17, the land information 607d is the information indicating the shape of a land 524 that is a soldering area of the electronic component 508. It should be noted that mask information indicating the shape of a mask to be used for applying cream solder to the circuit board 20 may be used in the case where the land information 607d is not available.

The board contour information 607e is the data indicating the contour information of the circuit board 20 before components are mounted thereon.

<Support Pin Position Determination Processing>

Next, the support pin position determination process performed by the above-mentioned support pin position determination apparatus 600 is described by referring to the drawings.

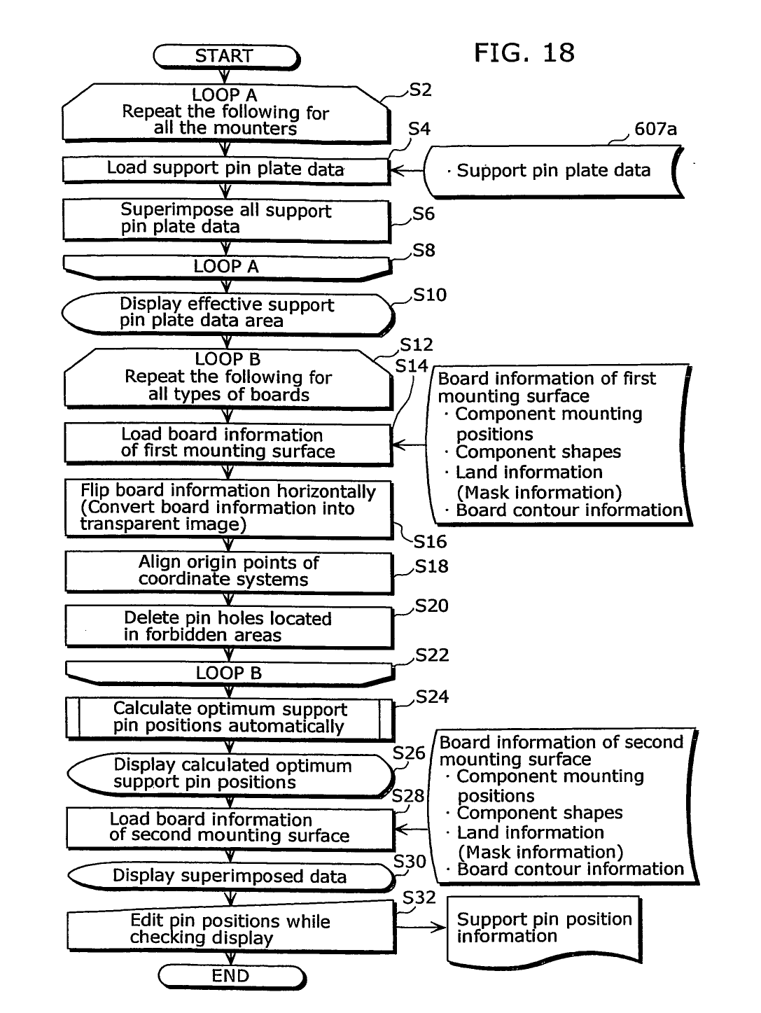

FIG. 18 is a flowchart of the support pin position determination processing.

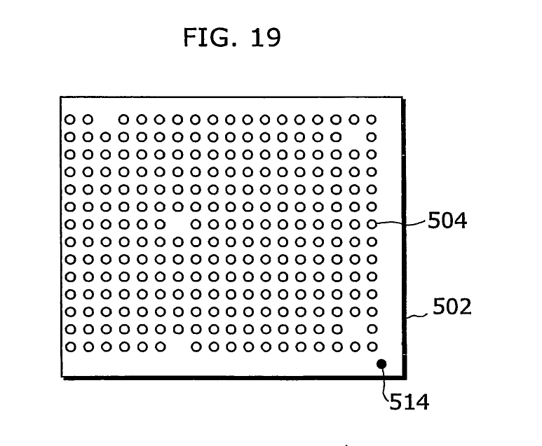

The calculation control unit 601 loads the support pin plate data 607a as shown in FIG. 15 from the database unit 607 of each mounter 100 (S4). The loaded support pin plate data 607a of all the mounters 100 are superimposed with the reference hole 514 as the base point (S6). According to this process, pin holes 504 that overlap with each other in all the support pin plate data 607a are obtained, and an effective support pin plate data area is created and displayed on the display unit 602 (S10). For example, the effective support pin-plate data-area as shown in FIG. 19 is created and displayed.

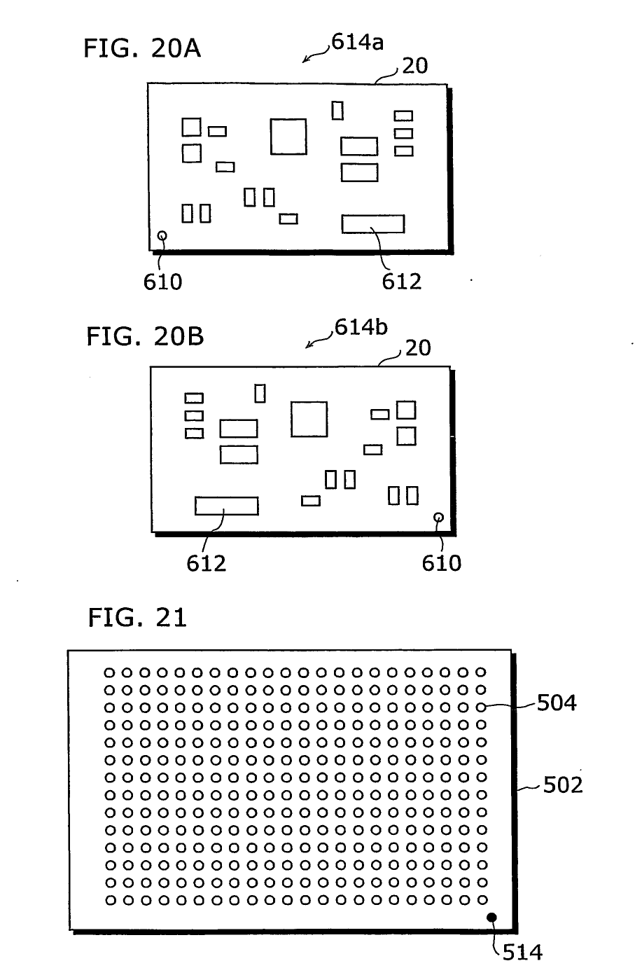

Next, the following processes are repeated for all types of the circuit boards 20 on which the components are to be mounted (all the layout patterns of electronic components to be mounted on the circuit boards 20) during a certain period of time (one day, for example). More specifically, as for the first mounting surface of a circuit board 20 (one surface of a double-sided board, on which the components are to be mounted first), the mounting point data 607b, the component shape data 607c, the land information 607d and the board contour information 607e are loaded, and mounting board information 614a as shown in FIG. 20A is created (S14). In more detail, the mounting board information 614a indicates an forbidden areas 612 on the circuit board 20 where the support pin 510 should not be set up because the component, leads, lands and the like are placed thereon. It should be noted that the forbidden area 612 where the support pins 510 should not be set up is obtained based on the circumscribed rectangle 522. The circumscribed rectangle 522 is obtained by adding a margin of a fixed width 520 around the circumscribed rectangle 519 including the electronic component 508 or another electronic component and the leads 518 thereof, as mentioned above. Therefore, using this method, the forbidden area 612 can be obtained by an easy process. Note that the circumscribed rectangle 522 may be obtained using the positions and shapes of leads and the positions and shapes of lands of the electronic component, not using the fixed width margin 520. It is possible to obtain the forbidden area 612 with high precision if the circumscribed rectangle 522 is obtained in the above manner, but necessary to refer to all the positions and shapes of the leads and lands of the electronic components. Therefore, the process of obtaining the forbidden area 612 is relatively complicated. It should be noted that the mounting board information 614a also has a reference hole 610 for aligning it with the support pin plate 502.

Next, flipped mounting board information 614b as shown in FIG. 20B is created (S16). This flipped mounting board information 614b is a horizontally-flipped version of the mounting board information 614a. The mounting board information 614a is flipped horizontally for obtaining the positions of the support pins 510 at which the pins come in contact with the first mounting surface that is the undersurface of the circuit board when the components are mounted on the second mounting surface (the surface on which the components are to be mounted in the next place).

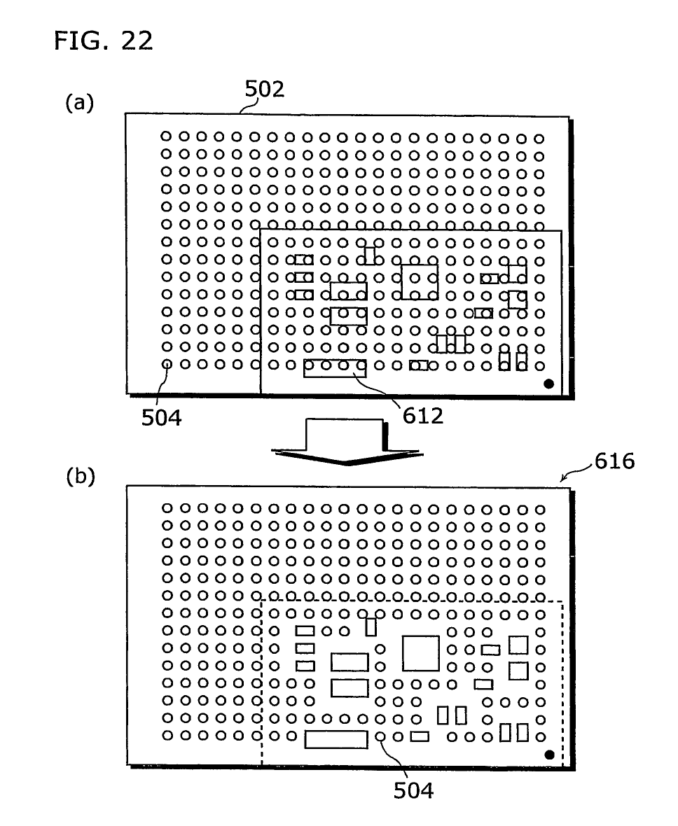

Next, the flipped mounting board information 614b is superimposed on the effective support pin plate data area calculated in the effective support pin plate data area calculation process (S2 to S8) with the reference hole as a base point, so as to create superimposed data (S18). For simple explanation, the effective support pin plate data area shall be the area as shown in FIG. 21. FIG. 22(a) shows the superimposed data obtained as a result of superimposing the effective support pin plate data area and the flipped mounting board information 614b as shown in FIG. 20B.

As a result of the superimposition, pin holes 504 included in the forbidden area 612 where support pins 510 should not be set up are deleted from the superimposed data, so as to create support pin position data 616 as shown in FIG. 22(b) (S20). In other words, the support pins 510 can be set up at the positions where the pin holes 504 still remain on the support pin position data 616.

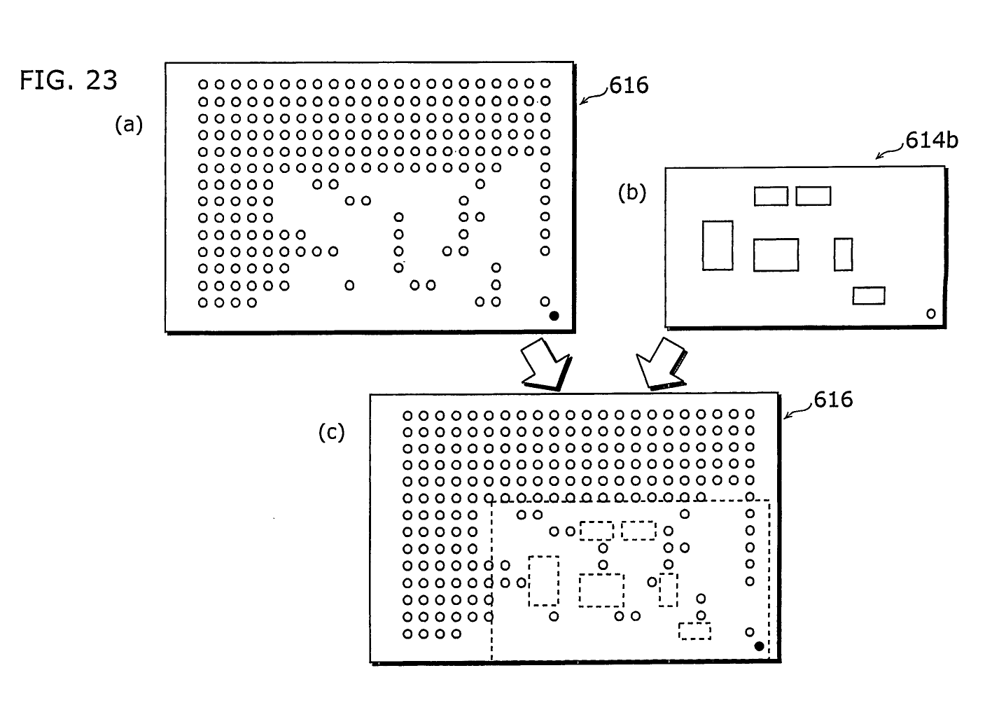

Next, the process of superimposing the flipped mounting board information 614b of another type of board on the support pin position data 616, so as to update the support pin position data 616 (S14 to S20). For example, by superimposing the support pin position data 616 as shown in FIG. 23(a) and the flipped mounting board information 614b as shown in FIG. 23(b), the support pin position data 616 is updated as shown in FIG. 23(c). This process is performed for all the mounting boards, so as to finally create the support pin position data 616 (S12 to S22).

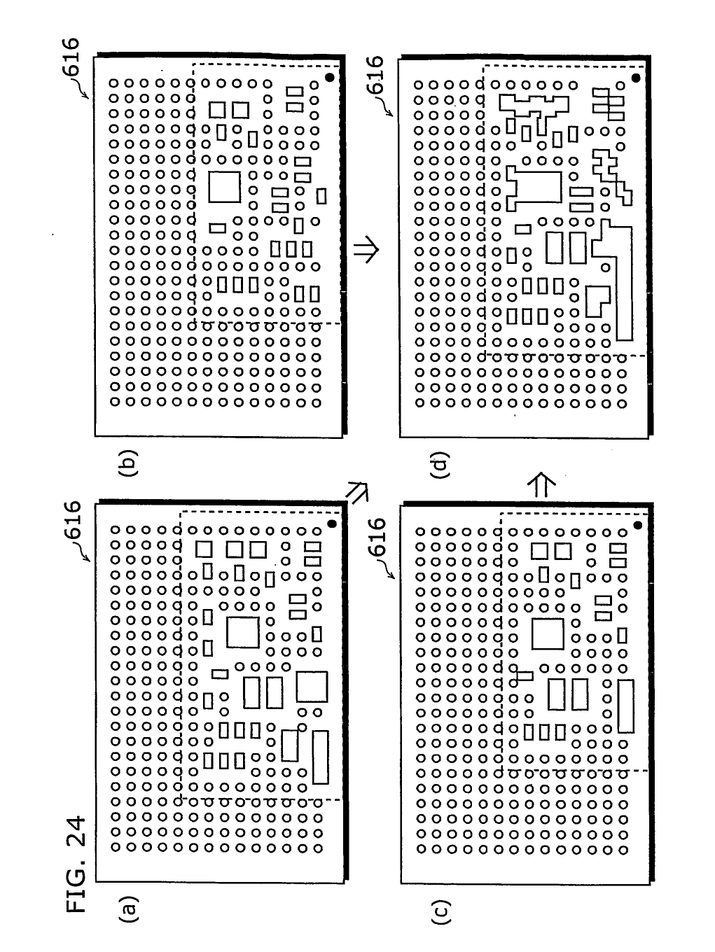

In sum, as shown in FIG. 24, by superimposing all the support pin position data 616 for the circuit boards as shown in FIG. 24(a) to FIG. 24(c), the support pin position data 616 as shown in FIG. 24(d) is finally obtained.

Next, the optimum support pin positions are automatically calculated from the obtained support pin position data 616, so as to create the support pin position information (S24). In other words, the optimum positions of the support pins 510 are automatically determined so that they are placed without concentration to a specific area and support all over the circuit board 20 while preventing the bending thereof. This process is described later.

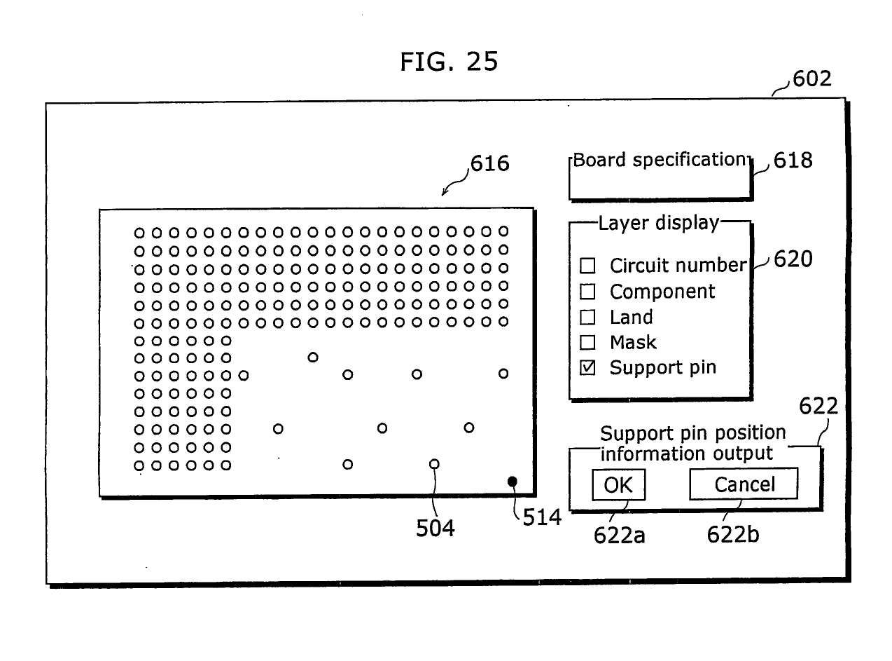

The automatically calculated support pin position information is displayed on the display unit 602 (S26). FIG. 25 is a diagram showing one example of the support pin position information displayed on the display unit 602. The support pin position data 616 is displayed at the left side of the display unit 602, while a board specification window 618, a layer display window 620, and a support pin position information output window 622 are displayed at the right side of the display. The circuit board to be displayed on the support pin position data 616 is specified in the board specification window 618, the information to be displayed on the support pin position data 616 is specified in the layer display window 620, and it is specified in the support pin position information output window 622 whether or not the support pin position data 616 is outputted as support pin position information. It should be noted that FIG. 25 is just an example of display, and the display unit 602 may display any other information and in any other manner.

A board number is inputted in the board specification window 618 to specify a circuit board. The layer display window 620 includes checkboxes for marking a circuit number, a component, a land, a mask and a support pin. These five information items have a multilayer structure, and it is possible to display a plurality of information superimposed in layers on the screen when marking a plurality of checkboxes. Since only the support pin checkbox is marked in FIG. 25, only the pin holes 504 and the reference hole 514 are displayed on the support pin position data 616. The support pin position information output window 622 includes an OK button 622a and a cancel button 622b.

By clicking the OK button 622a, a user can output, as support pin position information, the support pin position data 616 in the process of being edited, and writes it into the database unit 607.

The user can stop the editing by clicking the OK button 622a. It should be noted that the support pin position data 616 is edited by changing the positions of the pin holes 504 while operating the input unit 603.

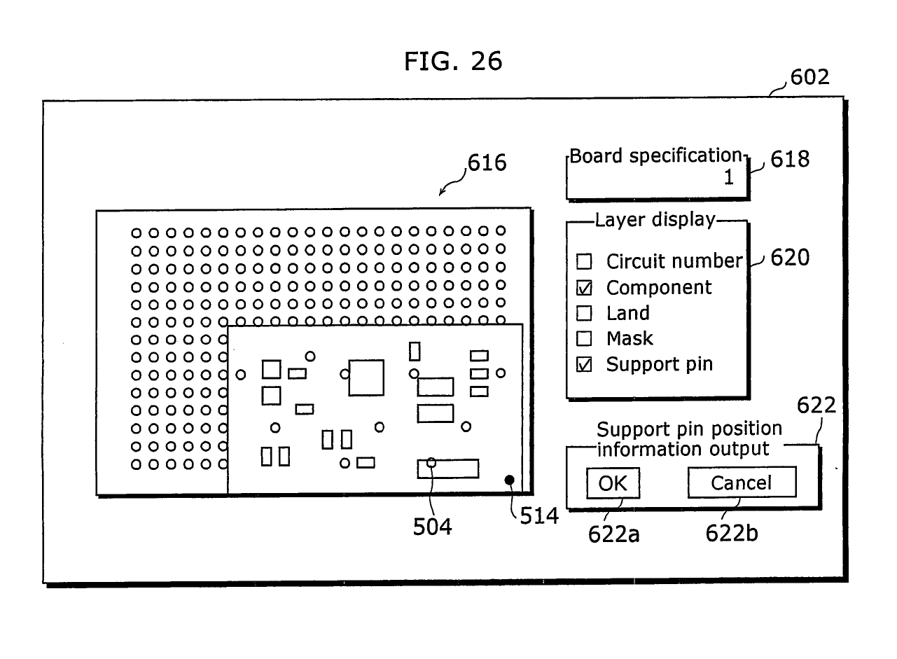

For example, as shown in FIG. 26, when the user marks the support pin checkbox and the component checkbox on the layer display window 620 and inputs the number of the circuit board 20 into the board specification window 618, the board information of the second mounting surface of the circuit board 20 that corresponds to that number is loaded from the database unit 607 to the calculation control unit 601 (S28). Then, the pin holes 504, the reference hole 514 and the components to be mounted on the second mounting surface are superimposed and displayed on the support pin position data 616 (S30). Since the components to be mounted on the second mounting surface are also displayed, the support pin position data 616 can be edited so that the pin hole 504 is placed immediately below the component to be on the second mounting surface (S32). By editing the pin positions in the manner as mentioned above, the places where the components are to be mounted are properly supported by the support pins 510, so it becomes possible to prevent the bending of the circuit board 20 when the components are mounted thereon.

When the OK button 622a is clicked after the above-mentioned editing, the support pin position data 616 is written as the support pin position information into the database unit 607, and the processing is terminated.

It should be noted that since no component is mounted on the first mounting surface in the case where the components are mounted only one surface of the circuit board on the mounting line, there is no restriction area on the first mounting surface where the support pins cannot be placed due to overlapping with the mounted components. Therefore, the support pins are placed at the positions where they support the immediate surroundings of the components to be mounted on the second mounting surface.

In addition, it is unnecessary to perform the process of automatically calculating the support pin positions. In other words, the pin positions may be determined manually within the permissible range of the support pin position data 616, using the editing function.

<Automatic Optimum Support Pin Position Calculation Process>

Next, the automatic optimum support pin position calculation process (S24 in FIG. 18) is described in detail by referring to the drawings. In this process, the positions of the support pins 510 are automatically determined so that the available support pins 510 are placed without concentration to a specific area and support all over the circuit board 20 while preventing the bending thereof.

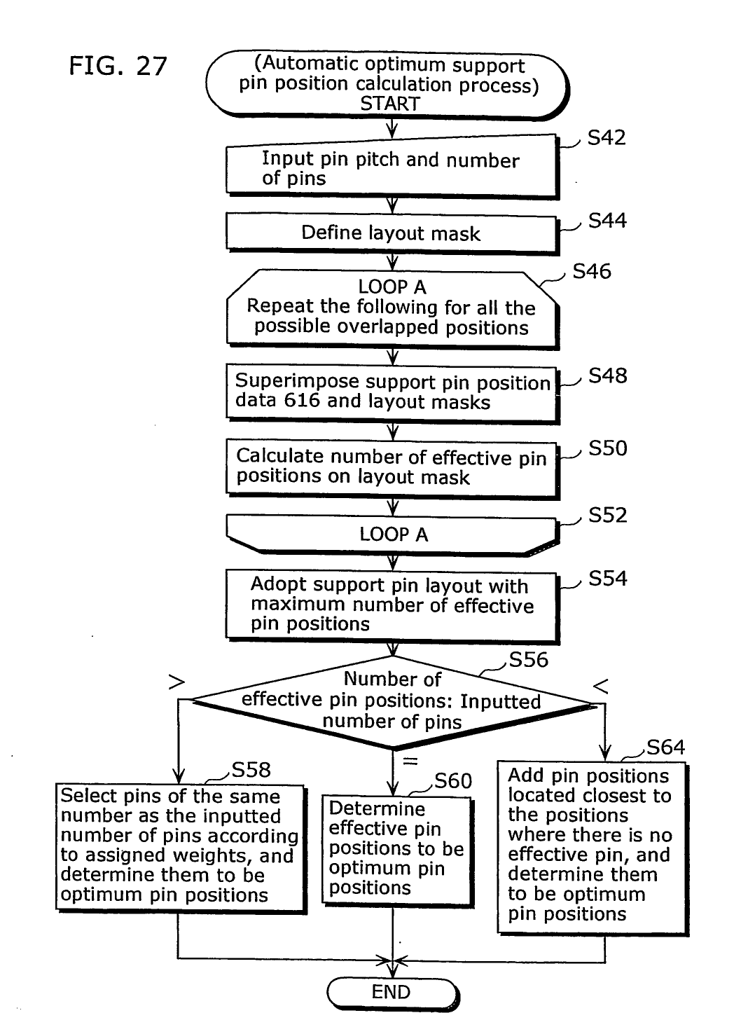

FIG. 27 is a flowchart of the automatic optimum support pin position calculation process.

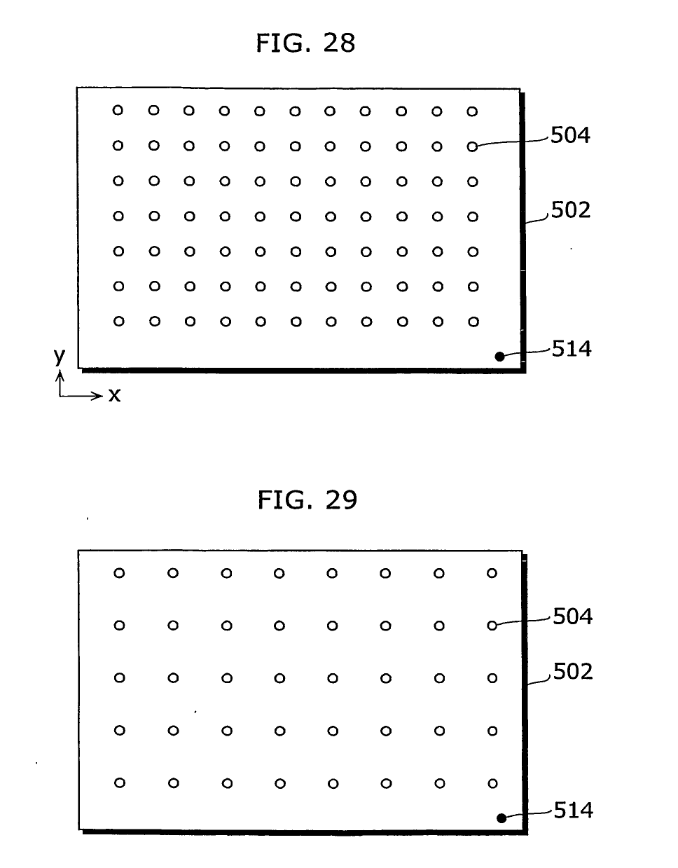

First, the user inputs the pin pitch and the number of pins required for supporting the circuit board 20 (S42). The ideal layout mask is defined based on the inputted pin pitch (S44). For example, the pitch “1” is specified for the support pin plate data as shown in FIG. 21, the ideal layout mask as shown in FIG; 28 is created. In more detail, the pin holes 504 are selected every other one from the pin holes on the support pin plate data as shown in FIG. 21, so as to create the ideal layout mask. When the pitch “2” is specified, pin holes 504 are further selected every other one from the pin holes on the layout mask as shown in FIG. 28, so as to create the ideal layout mask as shown in FIG. 29.

Next, the following processes are repeated for all the possible overlapped positions of pin holes on the layout masks (S46 to 552). For example, the following four types of layout masks are created: the layout mask as shown in FIG. 28; a layout mask on which the pin holes are shifted by one pitch in the X direction from those as shown in FIG. 28; a layout mask on which the pin holes are shifted by one pitch in the Y direction; and a layout mask on which the pin holes are shifted by one pitch in both the X and Y directions respectively.

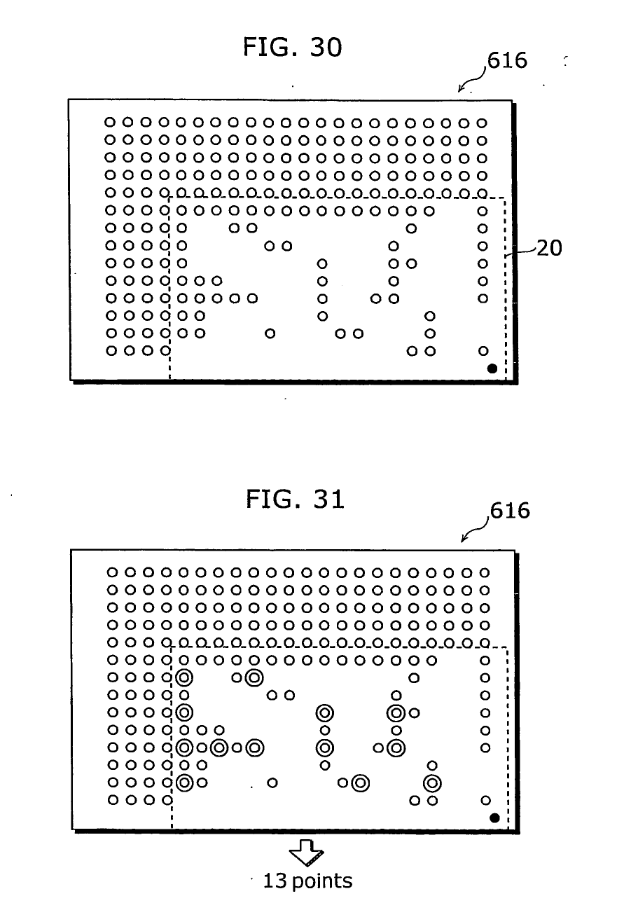

Each of these four types of layout masks is superimposed on the support pin position data 616 as shown in FIG. 30 (S48). The circuit board 20 displayed on the support pin position data 616 has the maximum size among all the circuit boards on which the components are to be mounted.

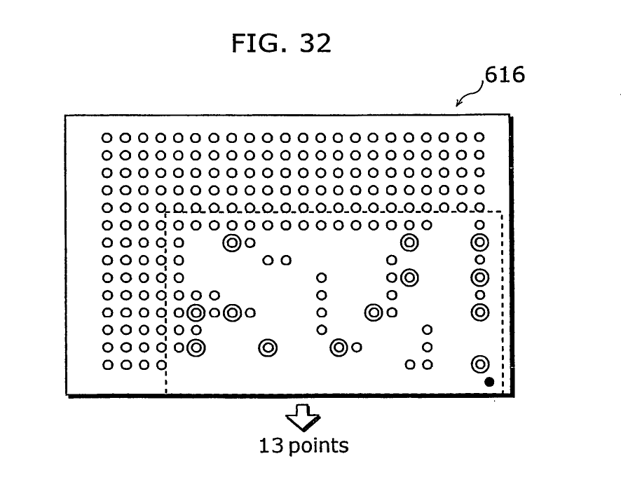

As a result of superimposing each of the four types of layout masks on the support pin position data 616, the number of effective pin positions on the circuit board 20 is calculated (S50). For example, when the layout mask as shown in FIG. 28 and the support pin position data 616 as shown in FIG. 30 are superimposed, the effective pin positions at which the pin positions on both the layout mask and the support pin position data 616 overlap with each other are double circles in FIG. 31, and the number of the positions is 13. Similarly, when the layout mask on which the pin holes are shifted by one pitch in the X direction from those as shown in FIG. 28 is superimposed on the support pin position data 616 as shown in FIG. 30, the effective pin positions are indicated by double circles in FIG. 32, and the number of the positions is 13.

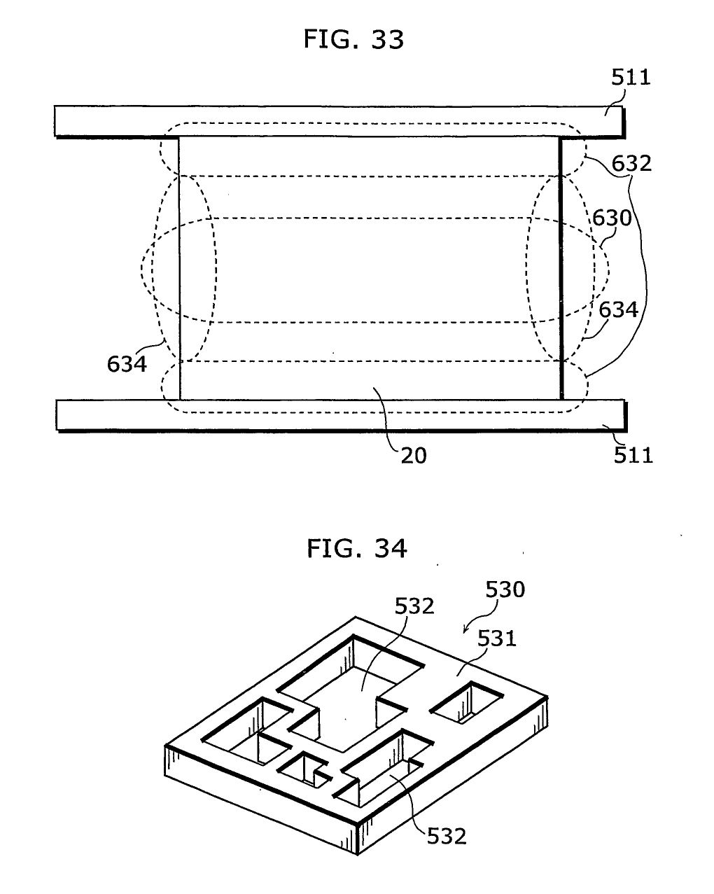

The support pin layout with the maximum number of effective support pin positions is adopted from among all the possible overlapped positions obtained in the above manner (S54). However, in the case where there are two or more support pin layouts with the maximum number of effective pin positions as shown in FIG. 31 and FIG. 32, for example, the weights are assigned to the support pin positions, and the support pin layout with the maximum number of weighted effective pin positions is adopted. The weights are assigned in the manner as shown in FIG. 33, for example. In more detail, it may be determined so that smaller weights are assigned to the support pins placed in horizontal edge parts 632 of the circuit board 20 that are supported by the carrier rails 511, while larger weights are assigned to the support pins placed in a center part 630 and vertical edge parts 634 of the circuit board 20 that are not supported by the carrier rails 511.

The number of effective pin positions included in the support pin layout calculated in the above manner is compared with the number of pins inputted by the user (S56). When both the numbers are same (“=” in S56), it is determined that the effective pin positions included in the support pin layout adopted in the support pin position adoption process (S54) is the optimum support pin positions (S60), and the processing is terminated.

When the number of effective support pin positions is larger than the inputted number of pins (“>” in S56), the effective support pins of the same number as the inputted number of pins are selected in descending order of weights assigned to the pins, the selected effective support pin positions are determined to be the optimum support pin positions (S58), and the processing is terminated.

When the number of effective support pin positions is smaller than the inputted number of pins (“<” in S56), the pin positions that are short in number are made effective from among the ineffective pin positions located closest to the areas where there is neither effective nor available pin position in the adopted layout mask, the effective support pin positions are determined to be the optimum support pin positions (S64), and the processing is terminated. Or, the support pin positions that are currently ineffective may be made effective so as to complement the areas where there is no pin position, in descending order of size in area.

The automatic optimum support pin position calculation process (S24 in FIG. 18) is performed in the above manner. In this process, the support pin positions are determined according to the ideal layout mask. Therefore, the support pin positions are determined so that the number of support pins placed per unit area is equal.

As described above, according to the present embodiment, the support pin positions are determined in consideration of leads and lands of electronic components. Therefore, there is no chance that the support pins hit the leads or lands on the undersurface of the board. In other words, there is no chance that the leads of the electronic components mounted on the undersurface of the board are damaged or the solder thereof comes off.

In addition, the support pin positions that are available in any of the layout patterns of multiple types of electronic components are obtained in the present embodiment. Therefore, there is no need to change the support pin positions even if the layout pattern of the electronic components is changed, which saves a user time and trouble.

Furthermore, in the present embodiment, the effective support pin plate data area is created after the support pin plate data of a plurality of mounters are superimposed, and then the support pin positions are obtained based on that area. Therefore, the plurality of mounters can share the support pin position information, and thus there is no need to change the support pin positions for each mounter.

Although the embodiment of the component mounting system according to the present invention has been described in detail above, the present invention is not limited to this embodiment.

For example, it is also possible that a sensor is provided on the support pin plate 502 of the mounter 100, the support pin position information is downloaded from the support pin position determination apparatus 600 to the mounter 100, and the mounter 100 issues a warning when a user mounts a support pin in a position other than the position where the user should mount it.

Moreover, it is also possible to configure the mounter 100 in the following manner. The support pins 510 are provided in advance below all the pin holes 504 of the support pin plate 502, the support pin position information is downloaded from the support pin position determination apparatus 600 to the mounter 100, and the support pins that should be placed at the determined positions are raised up through the pin holes automatically based on that information. Note that it is also possible to raise up the support pins mechanically using a motor or the like.

Furthermore, it is also possible, in the case of a multiple pattern board, not to place the support pins in the positions that correspond to the dividing sections on the board provided between the board layout patterns for dividing them. This is because the circuit board may be broken when components are mounted thereon, if the support pins are placed in the positions that correspond to the dividing sections that are easily broken. Note that the dividing section may be a series of holes at regular intervals or a perforated line.

Furthermore, in the automatic support pin position calculation process, the support pins may be placed preferentially below the components to be mounted on the second mounting surface. By doing so, it is possible to prevent the bending of the circuit board when components are mounted on the second mounting surface.

Moreover, in the process (S14 in FIG. 14) of calculating the mounting board information 614a based on the forbidden area 612 of the first mounting surface, as shown in FIG. 20A, where the support pin 510 should not be placed, this forbidden area 612 may be determined based on the image data of the component mounted on the first mounting surface of the circuit board 20 and its lands.

Furthermore, although the circuit board is supported using the support pin plate and the support pins in the above embodiment, it is possible to support the circuit board using a jig of a predetermined shape made by machining a massive material such as polyurethane foam, silicon resin or metal (iron, for example). FIG. 34 is a diagram showing one example of a jig made of polyurethane foam. A plurality of holes 532 are provided on a jig 530. A polyurethane unit 531 corresponds to a section where support pins 510 are set up. When the circuit board 20 is placed on the jig 530, the electronic components 508 mounted on the undersurface of the circuit board 20 fit into the holes 532. Therefore, it is possible to support the circuit board 20 by placing it on the jig 530 without damaging the electronic components 508 mounted on the undersurface of the circuit board 20. Note that the polyurethane unit 531 becomes deformed flexibly. Therefore, there is no problem if the electronic components 508 with lower heights do not fit into the holes 532 but come into contact with the polyurethane foam 531. In other words, even if the electronic components 508 with lower heights come into contact with the polyurethane foam 531, they are not damaged nor detached from the circuit board 20 because of the flexibility of the polyurethane unit 531. In addition, this type of jig 530 can also be used as a packing material after the electronic components 508 are mounted.

Furthermore, in the process of performing screen printing of wiring on a circuit board, a plate member called a support plate is used as a member for supporting the circuit board, but it is also possible to use a combination of the above-mentioned support pin plate and support pins, or a jig made of polyurethane foam, silicon resin, metal or the like, instead of the support plate.

Moreover, it is also possible to download the information used in the support pin position determination apparatus 600, such as the mounting point data 607b, the component shape data 607c, the land information 607d and the board contour information 607e, from the CAD apparatus to the support pin position determination apparatus 600 via the communication interface unit 306.

### INDUSTRIAL APPLICABILITY

The present invention can be applied to a support pin positioning apparatus that determines support pin positions for a mounter, and particularly to a support pin positioning apparatus or the like intended to be used for a mounter that mounts multiple types of components or for a plurality of mounters.

1. An apparatus that determines a layout pattern of one or more support members for supporting a board, comprising:
a mounting point data memory operable to hold mounting point data of a component to be mounted on a surface opposite to a mounting surface of the board;
a shape data memory operable to hold shape data of the component to be mounted on the opposite surface; and
a support member layout pattern determination unit operable to determine the layout pattern of the support members on the basis of the mounting point data of the component and enlarged-shape data that is data of a shape with a margin added around an outer shape of the component.

2. The apparatus according to claim 1,
wherein the support members are support pins for supporting the board, and
the support member layout pattern determination unit includes:
a forbidden pin area determination unit operable to determine a forbidden pin area in which no support pin is allowed to be placed, on the basis of the mounting point data and the enlarged-shape data; and
a support pin position determination unit operable to determine pin positions at which the support pins are to be placed, on the basis of the forbidden pin area.

3. The apparatus according to claim 2,
wherein the forbidden pin area determination unit determines an enlarged area to be the forbidden pin area on the basis of the mounting point data and the shape data, the enlarged area being an area with a margin of a fixed width added around an outer shape of the component to be mounted on the board.

4. The apparatus according to claim 2,
wherein the forbidden pin area determination unit determines the forbidden pin area on the basis of the mounting point data, the shape data, a position of a land of the component, and a shape of the land.

5. The apparatus according to claim 2,
wherein the forbidden pin area determination unit determines the forbidden pin area on the basis of image data of the component to be mounted on the opposite surface and a land of said component.

6. The apparatus according to claim 2,
wherein the shape data held in the shape data memory is data of a shape of a size including the component and a lead of said component.

7. The apparatus according to claim 2, further comprising
a mask information memory operable to hold shape information of a mask to be used for applying solder to the board,
wherein the support pin position determination unit determines the pin positions on the basis of the forbidden pin area and the mask shape information.

8. The apparatus according to claim 2,
wherein the mounting point data memory holds mounting point data of each component to be mounted on each of a plurality of boards,
the shape data memory holds shape data of said each component to be mounted on said each board, and
the support pin position determination unit determines the pin positions on the basis of the forbidden pin area on said each board.

9. The apparatus according to claim 2, further comprising
an available pin position memory operable to hold available pin positions at which the support pins are allowed to be placed on a support pin plate.

10. The apparatus according to claim 9,
wherein the available pin position memory holds the available pin positions on a support pin plate of each of a plurality of mounters, and
the support pin position determination unit includes:
a common available pin position determination unit operable to determine common available pin positions that are common to the plurality of mounters, on the basis of the available pin positions of said each mounter; and
a common pin position determination unit operable to determine, among the common available pin positions, common pin positions at which the support pins are to be placed, on the basis of the forbidden pin area.

11. The apparatus according to claim 2, further comprising
a first pin position updating unit operable to update the pin positions determined by the support pin position determination unit so that a number of support pins per unit area is equal all over a support pin plate.

12. The apparatus according to claim 11,
wherein the first pin position updating unit includes:
a pin pitch input receiving unit operable to receive a pitch between the support pins which is inputted front outside; and
a first updating unit operable to update the pin positions determined by the support pin position determination unit so that the inputted pitch is maintained and a number of support pins to be placed on the support pin plate becomes maximum.

13. The apparatus according to claim 12,
wherein the first pin position updating unit further includes:
a pin number input receiving unit operable to receive a number of support pins to be placed on the support pin plate, said number of support pins being inputted from outside; and
a second updating unit operable to compare the number of support pins to be placed on the support pin plate obtained by the first updating unit with the inputted number of support pins, and in the case where the number of support pins obtained by the first updating unit is larger than the inputted number of support pins, updates the pin positions determined by the support pin position determination unit so that the number of support pins to be placed on the support pin plate becomes equal to the inputted number of support pins, in accordance with predetermined weights assigned to the support pins.

14. The apparatus according to claim 13,
wherein the weights are assigned to the support pins in accordance with a position of a carrier rail for carrying the board and a position of the board placed on said carrier rail.

15. The apparatus according to claim 13, further comprising
a second pin position updating unit operable to update the pin positions determined by the support pin position determination unit so that the support pins support, from under the board, surroundings of a point at which the component is to be mounted on said board.

16. The apparatus according to claim 12,
wherein the first pin position updating unit further includes:
a pin number input receiving unit operable to receive a number of support pins to be placed on the support pin plate, said number of support pins being inputted from outside; and
a second updating unit operable to compare the number of support pins to be placed on the support pin plate obtained by the first updating unit with the inputted number of support pins, and in the case where the number of support pins obtained by the first updating unit is smaller than the inputted number of support pins, updates the pin positions determined by the support pin position determination unit so that the number of support pins to be placed on the support pin plate becomes equal to the inputted number of support pins by adding a support pin which is located closest to the forbidden pin area from among pin positions which are determined based on the inputted pitch.

17. The apparatus according to claim 12,
wherein the first pin position updating unit further includes:
a pin number input receiving unit operable to receive a number of support pins to be placed on the support pin plate, said number of support pins being inputted from outside; and
a second updating unit operable to compare the number of support pins to be placed on the support pin plate obtained by the first updating unit with the inputted number of support pins, and in the case where the number of support pins obtained by the first updating unit is smaller than the inputted number of support pins, updates the pin positions determined by the support pin position determination unit so that the number of support pins to be placed on the support pin plate becomes equal to the inputted number of support pins by adding a support pin to areas where no support pin to be placed exists, in descending order of size in area.

18. The apparatus according to claim 2,
wherein the mounting point data memory further holds mounting point data of a component to be mounted on the mounting surface of the board,
the shape data memory further holds shape data of the component to be mounted on the mounting surface of the board, and
the support pin position determination unit determines, on the basis of the forbidden pin area, the pin positions so that the support pins support, from under the board, surroundings of a point at which the component is to be mounted on said board.

19. The apparatus according to claim 2,
wherein the support pin position determination unit does not place the support pins in a position that corresponds to a division section which is provided between a plurality of layout patterns on the board for dividing said plurality of layout patterns.

20. The support member layout pattern determination apparatus according to claim 2, further comprising:
a displaying unit operable to display the pin positions and a layout pattern of components to be mounted on the board that are superimposed on each other; and
an editing unit operable to edit the pin positions in accordance with an instruction from a user.

21. The apparatus according to claim 1,
wherein the support member is a massive member for supporting the board, and
the support member layout pattern determination unit determines a position of a hole in the massive member on the basis of the mounting point data and the enlarged-shape data.

22. The support member layout pattern determination apparatus according to claim 21,
wherein the massive member is made of one of polyurethane foam, silicon resin and metal.

23. An apparatus that determines a layout pattern of one or more support members for supporting a board, comprising:
a mounting point data memory operable to hold mounting point data of a component to be mounted on a mounting surface of the board;
a shape data memory operable to hold shape data of the component to be mounted on the mounting surface; and
a support member layout pattern determination unit operable to determine, on the basis of the mounting point data and the shape data of the component, the layout pattern of the support members so that the support members support, from under the board, surroundings of a point at which the component is to be mounted on said board.

24. The apparatus according to claim 23,
wherein the support members are support pins for supporting the board, and
the support member layout pattern determination unit determines, on the basis of the mounting point data and the shape data of the component, pin positions at which the support pins are to be placed so that the support pins support, from under the board, the surroundings of the point at which the component is being mounted on said board.

25. The apparatus according to claim 23,
wherein the support member is a massive member for supporting the board, and
the support member layout pattern determination unit determines, on the basis of the mounting point data and the shape data of the component, a shape of the massive member so that the massive member supports, from under the board, the surroundings of the point at which the component is being mounted on said board.

26. The apparatus according to claim 25,
wherein the massive member is made of one of polyurethane foam, silicon resin and metal.

27. A mounter that mounts a component onto a board,
wherein the board is placed on support members for supporting the board in accordance with a layout pattern of the support members determined by a support member layout pattern determination apparatus, and
the support member layout pattern determination apparatus includes:
a mounting point data memory operable to hold mounting point data of a component to be mounted on a surface opposite to a mounting surface of the board;
a shape data memory operable to hold shape data of the component to be mounted on the opposite surface; and
a support member layout pattern determination unit operable to determine the layout pattern of the support members on the basis of the mounting point data of the component and enlarged-shape data that is data of a shape with a margin added around an outer shape of the component.

28. The mounter according to claim 27,
wherein the support members are support pins for supporting the board,
the support member layout pattern determination unit includes:
a forbidden pin area determination unit operable to determine a forbidden pin area in which no support pin is allowed to be placed, on the basis of the mounting point data and the enlarged-shape data; and
a support pin position determination unit operable to determine pin positions at which the support pins are to be placed, on the basis of the forbidden pin area, and
the support pins are set up on a support pin plate in accordance with the pin positions determined by the support pin position determination unit.

29. A mounter that mounts a component onto a board, comprising:
a support pin plate on which one or more support pins are set up;
a sensor operable to check whether or not the support pins are set up; and
a warning unit operable to issue a warning when the support pin is set up at a wrong position, on the basis of pin positions determined by a support pin position determination apparatus, the pin positions being positions at which the support pins for supporting the board in the mounter are to be placed,
wherein the support pin position determination apparatus includes:
a mounting point data memory operable to hold mounting point data of a component to be mounted on a surface opposite to a mounting surface of the board;
a shape data memory operable to hold shape data of the component to be mounted on the opposite surface;
a forbidden pin area determination unit operable to determine a forbidden pin area in which no support pin is allowed to be placed, on the basis of the mounting point data and enlarged-shape data that is data of a shape with a margin added around an outer shape of the component; and
a support pin position determination unit operable to determine the pin positions at which the support pins are to be placed, on the basis of the forbidden pin area.

30. A mounter that mounts a component onto a board, comprising:
a support pin plate on which one or more support pins are set up;
said one or more support pins that are placed under pin holes on the support pin plate; and
a support pin placement unit that places the support pins automatically by raising up the support pins through the pin holes located at pin positions determined by a support pin position determination apparatus, the pin positions being positions at which the support pins for supporting the board in the mounter are to be placed,
wherein the support pin position determination apparatus includes:
a mounting point data memory operable to hold mounting point data of a component to be mounted on a surface opposite to a mounting surface of the board;
a shape data memory operable to hold shape data of the component to be mounted on the opposite surface;
a forbidden pin area determination unit operable to determine a forbidden pin area in which no support pin is allowed to be placed, on the basis of the mounting point data and enlarged-shape data that is data of a shape With a margin added around an outer shape of the component; and
a support pin position determination unit operable to determine the pin positions at which the support pins are to be placed, on the basis of the forbidden pin area.

31. A method for determining positions of one or more support pins for supporting a board in a mounter that mounts a component onto the board, comprising:
determining a forbidden pin area in which no support pin is allowed to be placed, on the basis of mounting point data of a component to be mounted on a surface opposite to a mounting surface of the board and enlarged-shape data that is data of a shape with a margin added around an outer shape of the component; and
determining pin positions at which the support pins are to be placed, on the basis of the forbidden pin area.

32. A computer-executable program for determining positions of one or more support pins for supporting a board in a mounter that mounts a component onto the board, the program causing a computer to execute:
determining a forbidden pin area in which no support pin is allowed to be placed, on the basis of mounting point data of a component to be mounted on a surface opposite to a mounting surface of the board and enlarged-shape data that is data of a shape with a margin added around an outer shape of the component; and
determining pin positions at which the support pins are to be placed, on the basis of the forbidden pin area.
